(19) United States
(12) Patent Application Publication
(10) Pub. No.: US 2023/0104260 A1
(43) Pub. Date: Apr. 6, 2023

(54) RADIATION-SENSITIVE RESIN COMPOSITION AND METHOD FOR FORMING RESIST PATTERN

(71) Applicant: JSR CORPORATION, Tokyo (JP)

(72) Inventors: Takuya OMIYA, Tokyo (JP); Katsuaki NISHIKORI, Tokyo (JP); Kazuya KIRIYAMA, Tokyo (JP); Natsuko KINOSHITA, Tokyo (JP)

(73) Assignee: JSR CORPORATION, Tokyo (JP)

(21) Appl. No.: 17/795,967

(22) PCT Filed: Jan. 20, 2021
(86) PCT No.: PCT/JP2021/001795

§ 371 Date: Jul. 28, 2022

(30) Foreign Application Priority Data
Feb. 6, 2020 (JP) 2020-019096

(51) Int. Cl. G03F 7/039; G03F 7/004; G03F 7/029; G03F 7/20

(52) U.S. Cl. CPC G03F 7/0392; G03F 7/0048; G03F 7/029; G03F 7/2004

(57) ABSTRACT

A radiation-sensitive resin composition includes a resin, a radiation-sensitive acid generator, and a solvent. The resin includes a structural unit A represented by formula (1) and a structural unit B having an acid-dissociable group. The structural unit represented by the formula (1) is excluded from the structural unit B. In the formula (1), A is a monovalent aromatic hydrocarbon group in which —OR^{Y} is bonded to a carbon atom adjacent to a carbon atom to which L^{α} is bonded, and hydrogen atoms on other carbon atoms are unsubstituted, or a part or all of the hydrogen atoms are substituted with a cyano group, a nitro group, an alkyl group, an alkoxy group, an alkoxycarbonyl group, an alkoxycarbonyloxy group, an acyl group, or an acyloxy group.

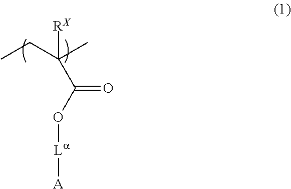

### BACKGROUND OF THE INVENTION

### Field of the Invention

The present invention relates to a radiation-sensitive resin composition and a method for forming a resist pattern.

### Description of the Related Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into an alkaline or organic developer between an exposed part and a non-exposed part.

In the above-described photolithography technology, the micronization of the pattern is promoted by using a short wavelength radioactive ray such as an ArF excimer laser or by using such a radioactive ray and an immersion exposure method (liquid immersion lithography) in combination. As a next-generation technology, a shorter wavelength radioactive ray such as an electron beam, an X ray, or EUV (extreme-ultraviolet ray) is tried to be used, and a resist material containing a styrene-based resin having an enhanced efficiency of absorbing such a radioactive ray is being studied (Patent Document 1).

### PRIOR ART DOCUMENT

### Patent Document

Patent Document 1: JP-A-2019-52294

### SUMMARY OF THE INVENTION

### Technical Problem

Even in the above-described next-generation technology, various resist performances equal to or higher than conventional ones are required in terms of sensitivity, line width roughness (LWR) performance indicating variation in line width of a resist pattern, and the like. Process margin that facilitates control of conditions for pattern miniaturization is desired. However, such characteristics of existing radiation-sensitive resin compositions are not at adequate levels.

It is an object of the present invention to provide a radiation-sensitive resin composition capable of exhibiting sensitivity, LWR performance, and process margin at adequate levels when used in the next-generation technology, and a method for forming a resist pattern.

### Solution to Problem

In order to achieve the above object, the present inventors have intensively studied, and as a result have found that the above object can be achieved by using the following. This finding has led to the completion of the present invention.

An embodiment of the present invention relates to a radiation-sensitive resin composition containing:

a resin that contains a structural unit A represented by the formula (1), and a structural unit B having an acid-dissociable group (except for a structural unit represented by the formula (1));

a radiation-sensitive acid generator; and

a solvent.

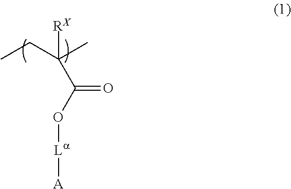

(wherein R^{X} is a hydrogen atom, a fluorine atom, a methyl group, or a trifluoromethyl group,

A is a monovalent aromatic hydrocarbon group in which —OR^{Y} is bonded to a carbon atom adjacent to a carbon atom to which L^{α} is bonded, and hydrogen atoms on other carbon atoms are unsubstituted, or a part or all of the hydrogen atoms are substituted with a cyano group, a nitro group, an alkyl group, an alkoxy group, an alkoxycarbonyl group, an alkoxycarbonyloxy group, an acyl group, or an acyloxy group, R^{Y} is a hydrogen atom or a protective group to be deprotected by the action of an acid, and

L^{α} is a single bond, or a divalent linking group.)

The radiation-sensitive resin composition contains the resin having the structural unit A, and therefore can exhibit sensitivity, LWR performance, and process margin at adequate levels. The reason for this is not clear, but can be expected as follows. The —OR^{Y} group bonded to the aromatic hydrocarbon group in the structural unit A is bonded to a carbon atom adjacent to a carbon atom to which L^{α} is bonded (i.e., ortho position with respect to La). It is expected that the —OR^{Y} group that can be a phenolic hydroxyl group is bonded in an ortho position with respect to L^{α} so as to face toward the main chain of the resin, and therefore the solubility of the resin in a developer in an unexposed area is reduced, which as a result greatly contributes to, for example, increased contrast between an exposed area and an unexposed area. When protected by a protective group to be deprotected by the action of an acid, the —OR^{Y} group becomes a phenolic hydroxyl group due to deprotection by the action of an acid so that the same contrast increasing effect as that described above is obtained. It is to be noted that the term “acid-dissociable group” refers to a group that substitutes for a hydrogen atom of an alkali-soluble group such as a carboxyl group, a phenolic hydroxyl group, a sulfo group, or a sulfonamide group and that dissociates due to the action of an acid. Therefore, the acid-dissociable group bonds to an oxygen atom that has been bonded to the hydrogen atom in such a functional group.

Another embodiment of the present invention relates to a method for forming a resist pattern, including:

forming a resist film from the radiation-sensitive resin composition;

exposing the resist film; and

developing the exposed resist film.

The method for forming a resist pattern uses the above-described radiation-sensitive resin composition excellent in sensitivity, LWR performance, and process margin, and therefore a high-quality resist pattern can efficiently be formed by lithography using a next-generation exposure technology.

### DETAILED DESCRIPTION OF THE PREFERRED EMBODIMENTS

Hereinbelow, embodiments of the present invention will be described in detail, but the present invention is not limited to these embodiments.

<<Radiation-Sensitive Resin Composition>>

A radiation-sensitive resin composition according to the present embodiment (hereinafter, also simply referred to as a “composition”) contains a resin, a radiation-sensitive acid generator, and a solvent. The composition may contain another optional component as long as the effects of the present invention are not impaired.

<Resin>

The resin is an assembly of polymers that have a structural unit A and a structural unit B (except for the structural unit A) (hereinafter, this resin will also be referred to as a “base resin”). The base resin may have a structural unit C having a phenolic hydroxy group and a structural unit D containing at least one selected from the group consisting of a lactone structure, a cyclic carbonate structure, and a sultone structure, in addition to the structural unit A, the structural unit B and the structural unit C. Hereinbelow, each of the structural units will be described.

### (Structural Unit A)

The structural unit A is represented by the formula (1).

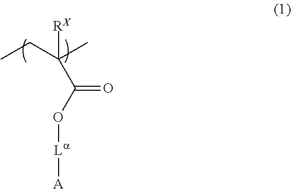

In the formula (1), R^{X} is a hydrogen atom, a fluorine atom, a methyl group or a trifluoromethyl group,

A is a monovalent aromatic hydrocarbon group in which —OR^{Y} is bonded to a carbon atom adjacent to a carbon atom to which L^{α} is bonded, and hydrogen atoms on other carbon atoms are unsubstituted, or a part or all of the hydrogen atoms are substituted with a cyano group, a nitro group, an alkyl group, an alkoxy group, an alkoxycarbonyl group, an alkoxycarbonyloxy group, an acyl group, or an acyloxy group, R^{Y} is a hydrogen atom or a protective group to be deprotected by the action of an acid, and

L^{α} is a single bond, or a divalent linking group.

The aromatic hydrocarbon group refers to a hydrocarbon group containing an aromatic ring structure as a ring structure. However, the aromatic hydrocarbon group is not required to be formed from only an aromatic ring structure, and may contain a chain structure or an alicyclic structure as a part thereof.

Examples of the aromatic hydrocarbon group represented by A include aromatic hydrocarbon groups such as aryl groups such as a phenyl group, a naphthyl group, an anthryl group, a phenanthryl group, and a pyrenyl group; and aralkyl groups such as a benzyl group, a phenethyl group, and a naphthylmethyl group. Among them, the aromatic hydrocarbon group is preferable.

In the aromatic hydrocarbon group represented by A, —OR^{Y} is bonded to a carbon atom adjacent to a carbon atom to which L^{α} is bonded. In other words, —OR^{Y} is bonded in an ortho position with respect to a carbon atom to which L^{α} is bonded. R^{Y} is a hydrogen atom or a protective group to be deprotected by the action of an acid. This makes it possible to appropriately reduce the solubility of the resin in an alkaline developer in an unexposed area, thereby exhibiting excellent LWR performance and the like.

Examples of the protective group to be deprotected by the action of an acid include groups represented by the following formulas (AL-1) to (AL-3).

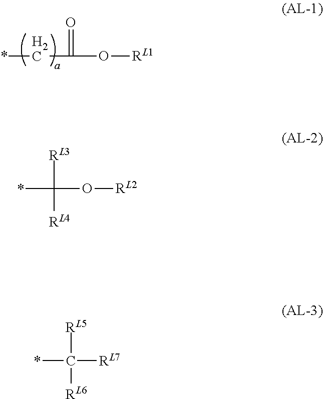

In the above formulas (AL-1) and (AL-2), R^{L1} and R^{L2} are each a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, more preferably an alkyl group having 1 to 20 carbon atoms. In the formula (AL-1), a is an integer of 0 to 10, preferably an integer of 1 to 5. In the above formulas (AL-1) to (AL-3), * represents a hand bonding to another moiety.

In the above formula (AL-2), R^{L3} and R^{L4} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{L2}, R^{L3}, and R^{L4} may be bonded together to form a ring having 3 to 20 carbon atoms together with a carbon atom or a carbon atom and an oxygen atom to which they are bonded. The ring is preferably a ring having 4 to 16 carbon atoms, particularly preferably an alicyclic ring.

In the above formula (AL-3), R^{L5}, R^{L6}, and R^{L7} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{L5}, R^{L6}, and R^{L7} may be bonded together to form a ring having 3 to 20 carbon atoms together with a carbon atom to which they are bonded. The ring is preferably a ring having 4 to 16 carbon atoms, particularly preferably an alicyclic ring.

Among them, the protective group to be deprotected by the action of an acid is preferably a group represented by the above formula (AL-3).

In A in the above formula (1), it is preferred that —OR^{Y} is not bonded to a carbon atom other than a carbon atom adjacent to a carbon atom to which L^{α} is bonded. This makes it possible to efficiently control the solubility in alkaline developer of the structural unit A in an unexposed area, thereby contributing to increasing contrast.

Examples of alkyl group capable of substituting a hydrogen atom on a carbon atom of the aromatic hydrocarbon group include: linear or branched alkyl groups having 1 to 8 carbon atoms, such as a methyl group, an ethyl group, and a propyl group; and monocyclic or polycyclic cycloalkyl groups having 3 to 20 carbon atoms. Examples of the alkoxy group include linear or branched alkoxy groups having 1 to 8 carbon atoms, such as a methoxy group, an ethoxy group, and a tert-butoxy group. Examples of the alkoxycarbonyl group include chain or alicyclic alkoxycarbonyl groups having 1 to 20 carbon atoms, such as a methoxycarbonyl group, a butoxycarbonyl group, and an adamantylmethyloxycarbonyl group. Examples of the alkoxycarbonyloxy group include chain or alicyclic alkoxycarbonyloxy groups having 2 to 16 carbon atoms, such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms, such as an acetyl group, a propionyl group, a benzoyl group, and an acryloyl group. Examples of the acyloxy group include aliphatic or aromatic acyloxy groups having 2 to 12 carbon atoms, such as an acetyloxy group, a propionyloxy group, a benzoyloxy group, and an acryloyloxy group.

Examples of the divalent linking group represented by L^{α} include an alkanediyl group, a cycloalkanediyl group, an alkenediyl group, *—R^{La}O—, and *—R^{Lb}COO— (* represents an oxygen-side bond). A part or all of the hydrogen atoms of these groups may be substituted with a halogen atom such as a fluorine atom or a chlorine atom, or a cyano group, or the like.

The alkanediyl group is preferably an alkanediyl group having 1 to 8 carbon atoms.

Examples of the cycloalkanediyl group include: monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propenediyl group, and a butenediyl group. The alkenediyl group is preferably an alkenediyl group having 2 to 6 carbon atoms.

Examples of R^{La} of *—R^{La}O— include the alkanediyl group, the cycloalkanediyl group, and the alkenediyl group. Examples of R^{Lb} of *—R^{Lb}COO— include the alkanediyl group, the cycloalkanediyl group, the alkenediyl group, and an arenediyl group. Examples of the arenediyl group include a phenylene group, a tolylene group, and a naphthylene group. The arenediyl group is preferably an arenediyl group having 6 to 15 carbon atoms.

The structural unit represented by the above formula (1) is preferably a structural unit represented by any one of the following formulas (1-1) to (1-4).

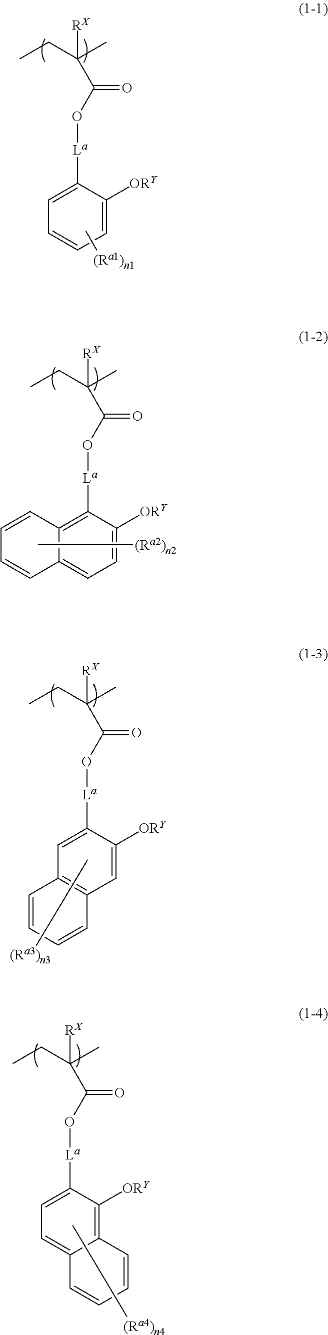

(wherein R^{X}, R^{Y} and L^{α} are the same as those in the above formula (1),

R^{a1}, R^{a2}, R^{a3}, and R^{a4} are each independently a cyano group, a nitro group, an alkyl group, an alkoxy group, an alkoxycarbonyl group, an alkoxycarbonyloxy group, an acyl group, or an acyloxy group,

n1 is an integer of 0 to 4, n2, n3, and n4 are each independently an integer of 0 to 6, and when there are two or more R^{a1}s, R^{a2}s, R^{a3}s, or R^{a4}s, the two or more R^{a1}s, R^{a2}s, R^{a3}s, or R^{a4}s are the same or different from each other).

An alkyl group, an alkoxy group, an alkoxycarbonyl group, an alkoxycarbonyloxy group, an acyl group, and an acyloxy group represented by R^{a1}, R^{a2}, R^{a3}, and R^{a4} are the same as those in the above formula (1).

Among these, R^{X} is preferably a hydrogen atom or methyl group.

R^{Y} is preferably a hydrogen atom.

R^{a1}, R^{a2}, R^{a3}, and R^{a4} are each independently preferably an alkyl group or an alkoxy group.

n1 is preferably an integer of 0 to 2, more preferably 0 or 1. n2, n3, and n4 are each independently preferably an integer of 0 to 4, more preferably an integer of 0 to 2.

L^{α} is preferably a single bond or *—R^{La}O—. R^{La} is preferably an alkanediyl group. L^{α} is preferably a single bond.

Preferred examples of the structural unit A include structural units represented by the formulas (A-1) to (A-12).

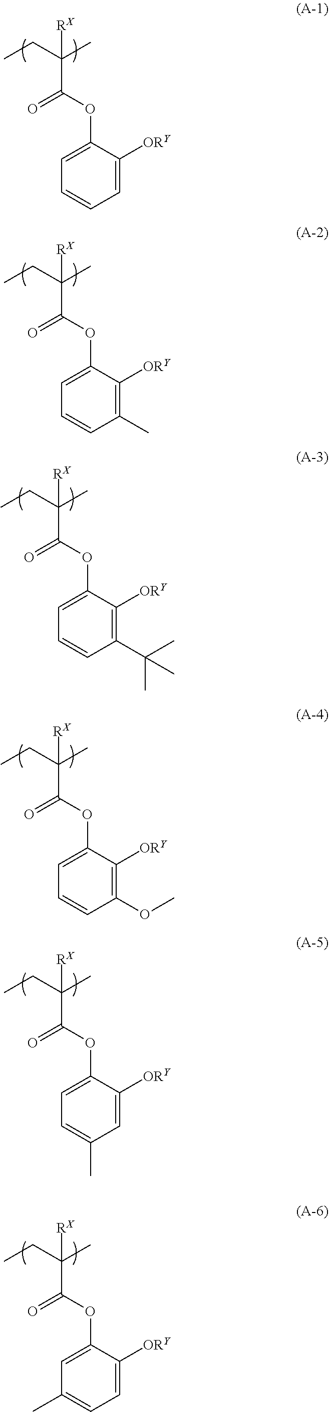

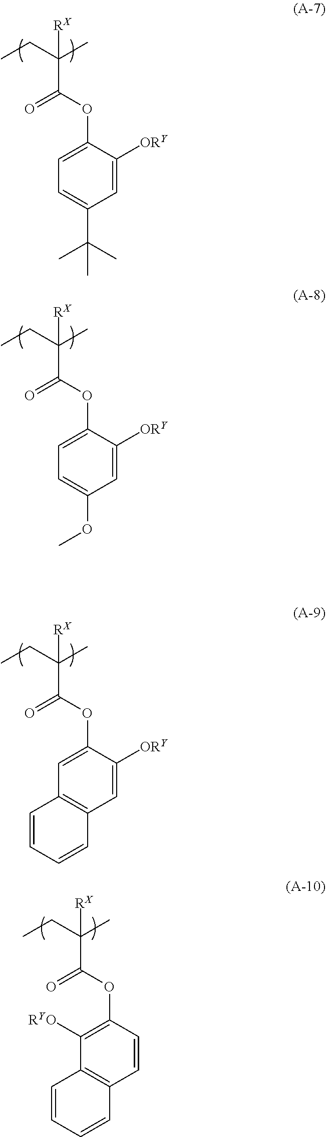

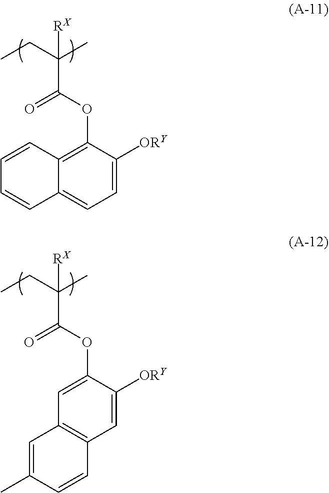

(wherein R^{X} and R^{Y} are the same as those in the above formula (1)).

Among them, structural units represented by the above formulas (A-1) to (A-4) and (A-9) to (A-11) are preferred.

A method for synthesizing a monomer compound that gives a structural unit A will be described by taking a monomer that gives a structural unit represented by the above formula (A-1) as an example. The monomer compound giving the structural unit represented by the above formula (A-1) can be synthesized according to the following scheme.

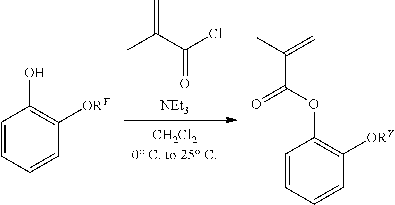

(In the above scheme, R^{Y} is the same as those in the above formula (1)).

In the presence of a base, a nucleophilic substitution reaction between a 1,2-dihydroxybenzene derivative having a structure corresponding to an aromatic hydrocarbon group in the above formula (1) and an acyl halide having a polymerizable group (methacryloyl chloride in the scheme) is allowed to proceed in a solvent, whereby a monomer compound can be synthesized. Other structures can be similarly synthesized by controlling the structure of the dihydroxy aromatic hydrocarbon derivative as a starting material.

The lower limit of the content of the structural unit A in the resin is preferably 2 mol %, more preferably 4 mol %, further preferably 5 mol % with respect to the total amount of the structural units constituting the resin. The upper limit of the content is preferably 70 mol %, more preferably 50 mol %, further preferably 30 mol %. When the content of the structural unit A is set to fall within the above range, the radiation-sensitive resin composition can have further improved sensitivity, LWR performance, and process margin.

### (Structural Unit B)

The structural unit B is different from the structural unit A and contains an acid-dissociable group. The structural unit B is not particularly limited as long as it contains an acid-dissociable group. Examples of such a structural unit C include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive resin composition, a structural unit represented by the following formula (2) (hereinafter also referred to as a “structural unit (B-1)”) is preferred.

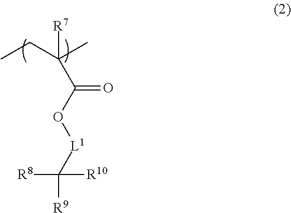

In the above formula (2), R⁷ is a hydrogen atom, a fluorine atom, a methyl group, or a trifluoromethyl group, R⁸ is a hydrogen atom or a monovalent hydrocarbon group having 1 to 20 carbon atoms, R⁹ and R¹⁰ are each independently a monovalent chain hydrocarbon group having 1 to 10 carbon atoms or a monovalent alicyclic hydrocarbon group having 3 to 20 carbon atoms or represent a divalent alicyclic group having 3 to 20 carbon atoms formed by these groups combined together and a carbon atom to which they are bonded, and L¹ is a single bond or a divalent linking group, and when L¹ is a divalent linking group, a carbon atom bonded to an oxygen atom of —COO— in the above formula (2) is a tertiary carbon or a side chain end-side structure is —COO—.

From the viewpoint of copolymerizability of a monomer that will give the structural unit (B-1), R⁷ is preferably a hydrogen atom or a methyl group, more preferably a methyl group.

Examples of the monovalent hydrocarbon group having 1 to 20 carbon atoms represented by R⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon groups having 1 to 10 carbon atoms represented by R⁸ to R¹⁰ include linear or branched saturated hydrocarbon groups having 1 to 10 carbon atoms and linear or branched unsaturated hydrocarbon groups having 1 to 10 carbon atoms.

Examples of the alicyclic hydrocarbon groups having 3 to 20 carbon atoms represented by R⁸ to R¹⁰ include monocyclic or polycyclic saturated hydrocarbon groups and monocyclic or polycyclic unsaturated hydrocarbon groups. Preferred examples of the monocyclic saturated hydrocarbon groups include a cyclopentyl group, a cyclohexyl group, a cycloheptyl group, and a cyclooctyl group. Preferred examples of the polycyclic saturated hydrocarbon groups include bridged alicyclic hydrocarbon groups such as a norbornyl group, an adamantyl group, a tricyclodecyl group, and a tetracyclododecyl group. It is to be noted that the bridged alicyclic hydrocarbon group refers to a polycyclic alicyclic hydrocarbon group in which two carbon atoms that constitute an alicyclic ring and not adjacent to each other are bonded by a bonding chain containing at least one carbon atom.

Examples of the monovalent aromatic hydrocarbon group having 6 to 20 carbon atoms represented by R⁸ include: aryl groups such as a phenyl group, a tolyl group, a xylyl group, a naphthyl group, and an anthryl group; and aralkyl groups such as a benzyl group, a phenethyl group, and a naphthylmethyl group.

R⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by R⁹ and R¹⁰ combined together and a carbon atom to which a chain hydrocarbon group or an alicyclic hydrocarbon group represented by R⁹ and a chain hydrocarbon group or an alicyclic hydrocarbon group represented by R¹⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Examples of the divalent linking group represented by L¹ include an alkanediyl group, a cycloalkanediyl group, an alkenediyl group, *—R^{LA}O—, *—R^{LB}COO— (* represents an oxygen-side bonding hand). However, in the case of the group other than *—R^{LB}COO—, a carbon atom bonded to an oxygen atom of —COO— in the above formula (2) is a tertiary carbon and does not have a hydrogen atom. The tertiary carbon is obtained when the same carbon atom in the group has two bonding hands or when one or two substituents are further bonded to a carbon atom having one of the bonding hands in the group.

A part or all of the hydrogen atoms on a carbon atom in R⁸ to R¹⁰ and L¹ may be substituted with a halogen atom such as a fluorine atom or a chlorine atom, a halogenated alkyl group such as a trifluoromethyl group, an alkoxy group such as a methoxy group, or a cyano group.

The alkanediyl group is preferably an alkanediyl group having 1 to 8 carbon atoms.

Examples of the cycloalkanediyl group include: monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propenediyl group, and a butenediyl group. The alkenediyl group is preferably an alkenediyl group having 2 to 6 carbon atoms.

Examples of R^{LA} of *—R^{LA}O— include the above-described alkanediyl group, the above-described cycloalkanediyl group, and the above-described alkenediyl group. Examples of R^{LB} of *—R^{LB}COO— include the above-described alkanediyl group, the above-described cycloalkanediyl group, the above-described alkenediyl group, and an arenediyl group. Examples of the arenediyl group include a phenylene group, a tolylene group, and a naphthylene group. The arenediyl group is preferably an arenediyl group having 6 to 15 carbon atoms.

Among them, R⁸ is preferably an alkyl group having 1 to 4 carbon atoms, and the alicyclic structure formed by R⁹ and R¹⁰ combined together and a carbon atom to which they are bonded is preferably a polycyclic or monocyclic cycloalkane structure. L¹ is preferably a single bond or *—R^{LA}O—. R^{LA} is preferably an alkanediyl group.

Examples of the structural unit (B-1) include structural units represented by the following formulas (3-1) to (3-6) (hereinafter also referred to as “structural units (B-1-1) to (B-1-6)”).

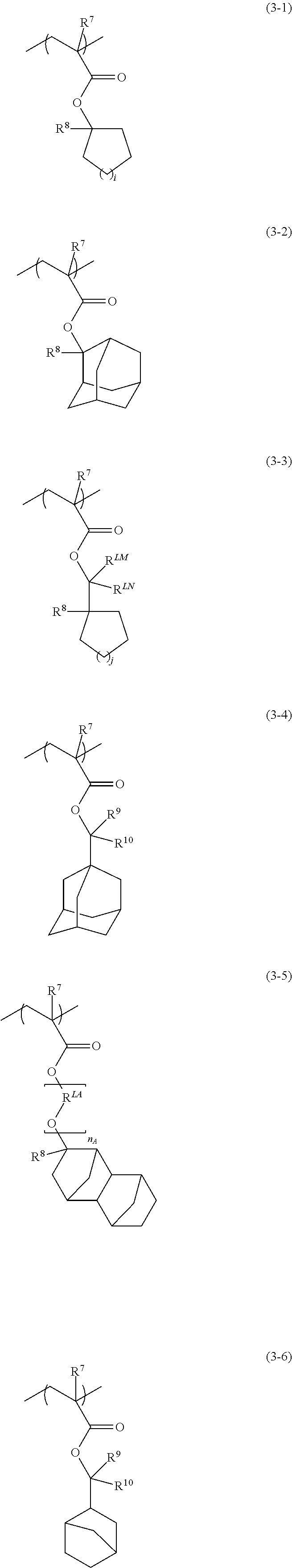

In the above formulas (3-1) to (3-6), R⁷ to R¹⁰ and R^{LA} are the same as those in the above formula (2), R^{LM} and R^{LN} are each independently a monovalent hydrocarbon group having 1 to 10 carbon atoms, i and j are each independently an integer of 1 to 4, and n_{A} is 0 or 1.

Examples of R^{LM} and R^{LN} include monovalent hydrocarbon groups having 1 to 10 carbon atoms out of the monovalent hydrocarbon groups having 1 to 20 carbon atoms represented by R⁸ in the above formula (2). R^{LM} and R^{LN} are each preferably a methyl group, an ethyl group, or an isopropyl group.

i and j are preferably 1. R⁸ to R¹⁰ are each preferably a methyl group, an ethyl group, or an isopropyl group.

Among them, the structural unit (B-1) is preferably a structural unit (B-1-1), a structural unit (B-1-2), a structural unit (B-1-4), or a structural unit (B-1-5). The structural unit (B-1-1) preferably has a cyclopentane structure. In the structural unit (B-1-5), n_{A} is preferably 0.

The base resin may contain one kind of structural unit B or a combination of two or more kinds of structural units B.

The resin may further contain, as another structural unit, a structural unit represented by the following formula (1f) or (2f).

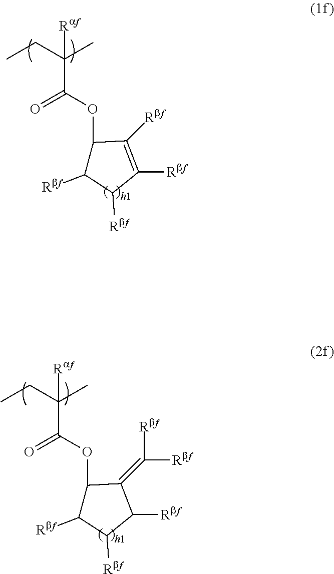

In the above formulas (1f) and (2f), R^{α}^{_{f}}s are each independently a hydrogen atom, a fluorine atom, a methyl group, or a trifluoromethyl group, R^{β}^{_{f}}s are each independently a hydrogen atom or a chain alkyl group having 1 to 5 carbon atoms, and hi is an integer of 1 to 4.

R^{β}^{_{f}}s are each preferably a hydrogen atom, a methyl group, or an ethyl group. hi is preferably 1 or 2.

When the resin includes the structural unit B, the lower limit of the content of the structural unit B is preferably 10 mol %, more preferably 15 mol %, even more preferably 20 mol %, particularly preferably 30 mol % with respect to the total amount of the structural units constituting the base resin. The upper limit of the content is preferably 90 mol %, more preferably 80 mol %, even more preferably 75 mol %, particularly preferably 70 mol %. When the content of the structural unit C is set to fall within the above range, the pattern-forming performance of the radiation-sensitive resin composition can further be improved.

### (Structural Unit C)

The resin preferably contains a structural unit C represented by the following formula (cf).

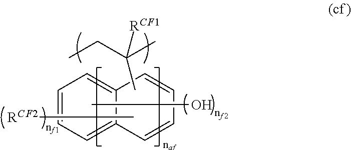

(wherein R^{CF1} is a hydrogen atom or a methyl group, R^{CF2} is a monovalent organic group having 1 to 20 carbon atoms or a halogen atom,

n_{f1} is an integer of 0 to 3, when n_{f1} is 2 or 3, two or more R^{CF2}s are the same or different, n_{f2} is an integer of 1 to 3, n_{f1}+n_{f2} is 5 or less, and n_{af} is an integer of 0 to 2).

The structural unit C is a structural unit that is different from the structural unit A and that contains a phenolic hydroxyl group. The resin contains the structural unit C and may optionally contain another structural unit to more appropriately adjust its solubility in a developer, which as a result makes it possible to further improve the sensitivity etc. of the radiation-sensitive resin composition. Further, when KrF excimer laser light, EUV, an electron beam, or the like is used as a radioactive ray for irradiation in an exposure step in a method for forming a resist pattern, the structural unit B contributes to improved etching resistance and improved difference in solubility in a developer between an exposed part and a non-exposed part (dissolution contrast). Particularly, the structural unit C is suitably used when a pattern is formed by exposure using a radioactive ray having a wavelength of 50 nm or less such as an electron beam or EUV.

From the viewpoint of copolymerizability of a monomer that will give the structural unit C, R^{CF1} is preferably a hydrogen atom.

It is to be noted that the organic group refers to a group containing at least one carbon atom.

Examples of the monovalent organic group having 1 to 20 carbon atoms represented by R^{CF2} include a monovalent hydrocarbon group having 1 to 20 carbon atoms, a group obtained by introducing a divalent heteroatom-containing group between two carbon atoms or at the bonding hand-side end of the hydrocarbon group, and a group obtained by substituting a part or all of the hydrogen atoms of the group or the hydrocarbon group with a monovalent heteroatom-containing group.

Examples of the monovalent hydrocarbon group having 1 to 20 carbon atoms represented by R^{CF2} include:

chain hydrocarbon groups such as alkyl groups such as a methyl group, an ethyl group, a propyl group, and a butyl group,

alkenyl groups such as an ethenyl group, a propenyl group, and a butenyl group, and

alkynyl groups such as an ethynyl group, a propynyl group, and a butynyl group;

alicyclic hydrocarbon groups such as cycloalkyl groups such as a cyclopropyl group, a cyclopentyl group, a cyclohexyl group, a cyclooctyl group, a norbornyl group, and an adamantyl group, and

cycloalkenyl groups such as a cyclopropenyl group, a cyclopentenyl group, a cyclohexenyl group, and a norbornenyl group; and

aromatic hydrocarbon groups such as aryl groups such as a phenyl group, a tolyl group, a xylyl group, a naphthyl group, and an anthryl group and

aralkyl groups such as a benzyl group, a phenethyl group, and a naphthylmethyl group.

R^{CF2} is preferably a chain hydrocarbon group or a cycloalkyl group, more preferably an alkyl group or a cycloalkyl group, even more preferably a methyl group, an ethyl group, a propyl group, a cyclopentyl group, a cyclohexyl group, a cyclooctyl group, or an adamantyl group.

Examples of the divalent heteroatom-containing group include —O—, —CO—, —CO—O—, —S—, —CS—, —SO₂—, —NR′—, and a group obtained by combining two or more of them. R′ is a hydrogen atom or a monovalent hydrocarbon group.

Examples of the monovalent heteroatom-containing group include a halogen atom such as a fluorine atom, a chlorine atom, a bromine atom, or an iodine atom, a hydroxy group, a carboxy group, a cyano group, an amino group, and a sulfanyl group (—SH).

Among them, a monovalent chain hydrocarbon group is preferred, an alkyl group is more preferred, and a methyl group is even more preferred.

n_{f1} is preferably an integer of 0 to 2, more preferably 0 or 1, even more preferably 0.

n_{f2} is preferably 1 or 2, more preferably 1.

n_{af} is preferably 0 or 1, more preferably 0.

Preferred examples of the structural unit B include structural units represented by the following formulas (c1-1) to (c1-7).

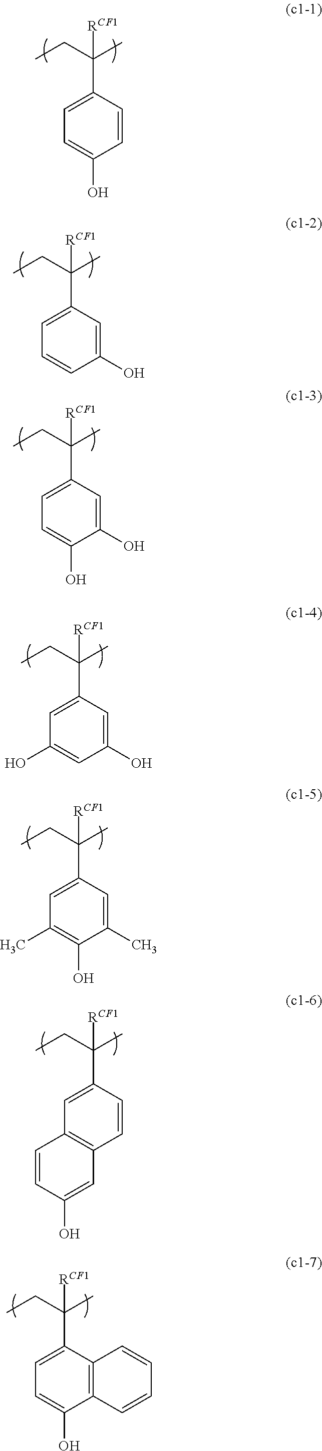

In the above formulas (c1-1) to (c1-7), R^{CF1} is the same as that in the above formula (cf).

Among them, structural units represented by the above formulas (c1-1) to (c1-4) and (c1-6) are preferred.

When the resin contains the structural unit C, the lower limit of the content of the structural unit C is preferably 2 mol %, more preferably 4 mol %, even more preferably 5 mol %, particularly preferably 8 mol % with respect to the total amount of all the structural units constituting the resin. The upper limit of the content is preferably 50 mol %, more preferably 45 mol %, even more preferably 40 mol %, particularly preferably 35 mol %. When the content of the structural unit C is set to fall within the above range, the sensitivity, LWR performance, and process margin of the radiation-sensitive resin composition can further be improved.

When monomers having a phenolic hydroxyl group such as hydroxystyrene are polymerized, it is preferred that polymerization is performed in a state where the phenolic hydroxyl group is protected by a protective group such as an alkali-dissociable group, and then hydrolysis is performed for deprotection to obtain the structural unit B. An example of a structural unit that will give the structural unit B by hydrolysis includes a structural unit represented by the following formula (c). Also in the case of another structure, a phenolic hydroxyl group present in the structure should be protected so that a resulting structural unit corresponds to the structural unit B.

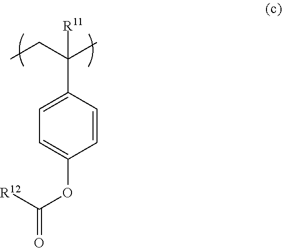

In the above formula (c), R¹¹ is a hydrogen atom, a fluorine atom, a methyl group, or a trifluoromethyl group. R¹² is a monovalent hydrocarbon group having 1 to 20 carbon atoms or an alkoxy group. Examples of the monovalent hydrocarbon group having 1 to 20 carbon atoms as R¹² include monovalent hydrocarbon groups having 1 to 20 carbon atoms. Examples of the alkoxy group include a methoxy group, an ethoxy group, and a tert-butoxy group.

R¹² is preferably an alkyl group or an alkoxy group. Among them, a methyl group or a tert-butoxy group is more preferred.

### (Structural Unit D)

The structural unit D is a structural unit including at least one selected from the group consisting of a lactone structure, a cyclic carbonate structure and a sultone structure. The solubility of the base resin into a developer can be adjusted by further introducing the structural unit D. As a result, the radiation-sensitive resin composition can provide improved lithography properties such as the resolution. The adhesion between a resist pattern formed from the base resin and a substrate can also be improved.

Examples of the structural unit D include structural units represented by the following formulae (T-1) to (T-10).

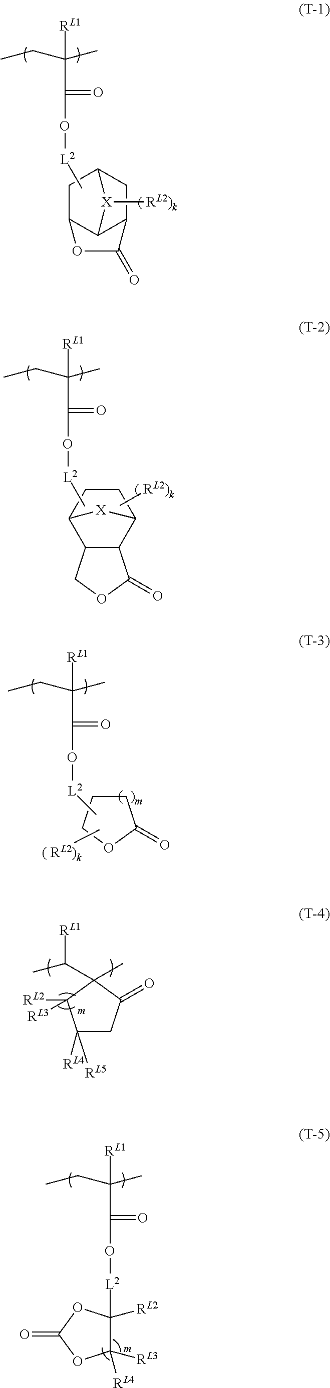

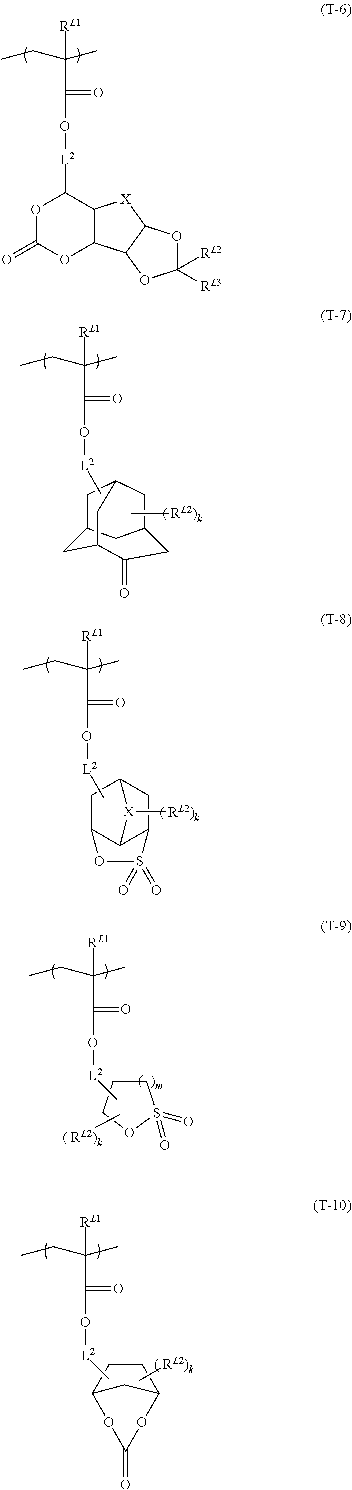

In the above formulae, R^{L1} is a hydrogen atom, a fluorine atom, a methyl group, or a trifluoromethyl group; R^{L2} to R^{L5} are each independently a hydrogen atom, an alkyl group having a carbon number of 1 to 4, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having a carbon number of 3 to 8, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Example of the divalent alicyclic group having a carbon number of 3 to 8, which is composed of a combination of R^{L4} and R^{L5} with the carbon atom to which they are bound, includes the divalent alicyclic group having a carbon number of 3 to 8 in the divalent alicyclic group having a carbon number of 3 to 20, which is composed of a combination of the chain hydrocarbon group or the alicyclic hydrocarbon group represented by R⁹ and R¹⁰ in the above formula (2) with the carbon atom to which they are bound. One or more hydrogen atoms on the alicyclic group may be substituted with a hydroxy group.

Examples of the divalent linking group represented by L² as described above include a divalent straight or branched chain hydrocarbon group having a carbon number of 1 to 10; a divalent alicyclic hydrocarbon group having a carbon number of 4 to 12; and a group composed of one or more of the hydrocarbon group thereof and at least one group of —CO—, —O—, —NH— and —S—.

Among them, the structural unit D is preferably a group having a lactone structure, more preferably a group having a norbornane lactone structure, and further preferably a group derived from a norbornane lactone-yl (meth)acrylate.

When the resin contains the structural unit D, the lower limit of the content by percent of the structural unit D is preferably 5 mol %, more preferably 8 mol %, and further preferably 10 mol % based on the total structural units as the component of the base resin. The upper limit of the content by percent is preferably 40 mol %, more preferably 30 mol %, and further preferably 20 mol %. By adjusting the content by percent of the structural unit D within the ranges, the radiation-sensitive resin composition can provide improved lithography properties such as the resolution. The adhesion between the formed resist pattern and the substrate can also be improved.

### (Another Structural Unit)

If necessary, the resin may have another structural unit other than the above-described structural units A to D. An example of the another structural unit includes a structural unit having a fluorine atom, an alcoholic hydroxyl group, a carboxy group, a cyano group, a nitro group, or a sulfonamide group (hereinafter also referred to as a “structural unit E”). Among them, a structural unit having a fluorine atom, a structural unit having an alcoholic hydroxyl group, and a structural unit having a carboxy group are preferred, and a structural unit having a fluorine atom and a structural unit having an alcoholic hydroxyl group are more preferred.

Examples of the structural unit E include structural units represented by the following formulas.

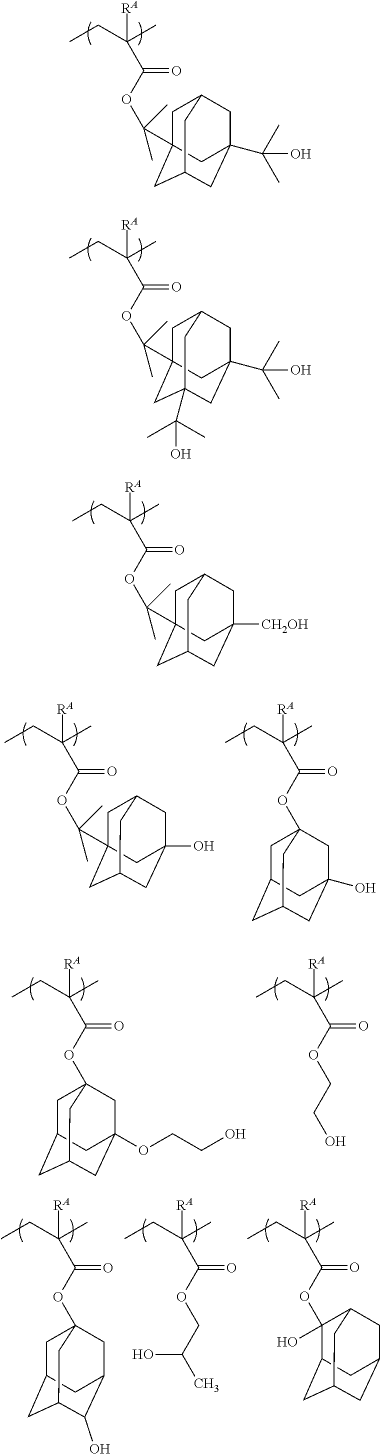

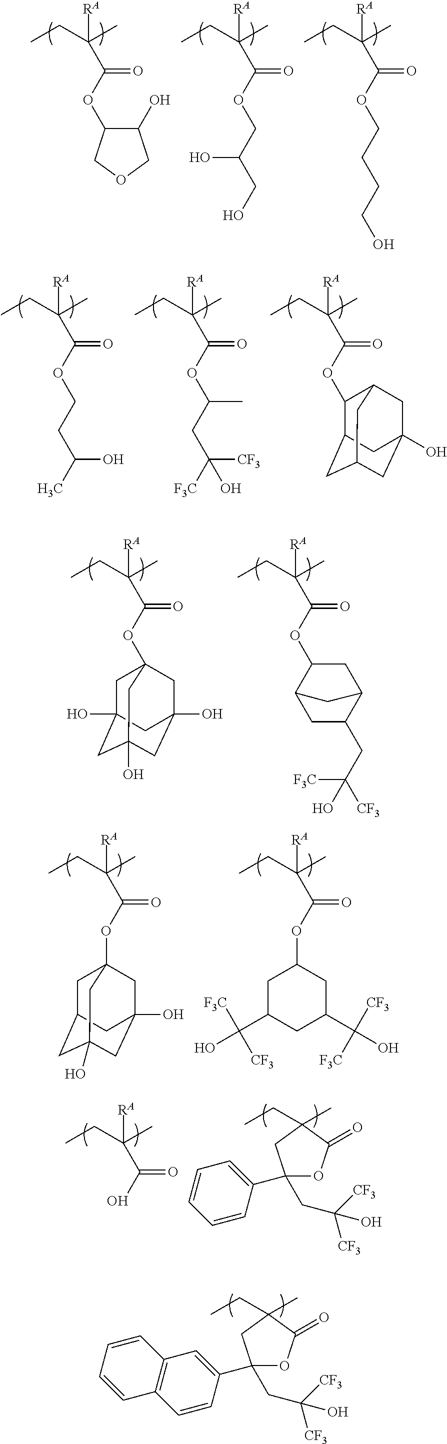

In the above formulas, R^{A} is a hydrogen atom, a fluorine atom, a methyl group, or a trifluoromethyl group.

When the resin has the structural unit E, the lower limit of the content of the structural unit E with respect to the total amount of the structural units constituting the resin is preferably 1 mol %, more preferably 3 mol %, even more preferably 5 mol %. On the other hand, the upper limit of the content is preferably 30 mol %, more preferably 20 mol %, even more preferably 15 mol %. When the content of the structural unit E is set to fall within the above range, the solubility of the resin in a developer can be made more appropriate.

It is to be noted that the structural units B to E do not include those falling under the structural unit A.

The content of the resin is preferably 70 mass % or more, more preferably 75 mass % or more, even more preferably 80 mass % or more with respect to the total solid content of the radiation-sensitive resin composition. Here, the term “solid” refers to all components contained in the radiation-sensitive resin composition except for a solvent.

(Synthesis Method of Base Resin)

For example, the resin as a base resin can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred, and AIBN is more preferred. The radical initiator may be used alone, or two or more radical initiators may be used in combination.

Examples of the solvent used for the polymerization reaction include

alkanes including n-pentane, n-hexane, n-heptane, n-octane, n-nonane, and n-decane;

cycloalkanes including cyclohexane, cycloheptane, cyclooctane, decalin, and norbornane;

aromatic hydrocarbons including benzene, toluene, xylene, ethylbenzene, and cumene;

halogenated hydrocarbons including chlorobutanes, bromohexanes, dichloroethanes, hexamethylenedibromide, and chlorobenzenes;

saturated carboxylate esters, including ethyl acetate, n-butyl acetate, i-butyl acetate, and methyl propionate;

ketones including acetone, methyl ethylketone, 4-methyl-2-pentanone, and 2-heptanone;

ethers including tetrahydrofuran, dimethoxyethanes, and diethoxyethanes; and

alcohols including methanol, ethanol, 1-propanol, 2-propanol, and 4-methyl-2-pentanol. The solvent used for the polymerization reaction may be used alone, or two or more solvents may be used in combination.

The reaction temperature of the polymerization reaction is typically from 40° C. to 150° C., and preferably from 50° C. to 120° C. The reaction time is typically from 1 hour to 48 hours, and preferably from 1 hour to 24 hours.

The molecular weight of the resin as a base resin is not particularly limited, and the weight average molecular weight (Mw) as determined by Gel Permeation Chromatography (GPC) relative to standard polystyrene is preferably 1,000 or more and 50,000 or less, more preferably 2,000 or more and 30,000 or less, still more preferably 3,000 or more and 15,000 or less, and particularly preferably 4,000 or more and 12,000 or less. When the Mw of the resin (A) is less than the lower limit, the heat resistance of the resulting resist film may be deteriorated. When the Mw of the resin (A) exceeds the above upper limit, the developability of the resist film may be deteriorated.

For the base resin as a base resin, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of the resin in the specification are amounts measured by using Gel Permeation Chromatography (GPC) with the condition as described below.

GPC column: two G2000HXL, one G3000HXL, and one G4000HXL (all manufactured from Tosoh Corporation) Column temperature: 40° C.

Eluting solvent: tetrahydrofuran

Flow rate: 1.0 mL/min

Sample concentration: 1.0% by mass

Sample injection amount: 100 μL

Detector: Differential Refractometer

Reference material: monodisperse polystyrene

The content of the resin is preferably not less than 70% by mass, more preferably not less than 80% by mass, and further preferably not less than 85% by mass based on the total solid content of the radiation-sensitive resin composition.

<Another Resin>

The radiation-sensitive resin composition according to the present embodiment may contain, as another resin, a resin having higher content by mass of fluorine atoms than the above-described base resin (hereinafter, also referred to as a “high fluorine-containing resin). When the radiation-sensitive resin composition contains the high fluorine-containing resin, the high fluorine-containing resin can be localized in the surface layer of a resist film compared to the base resin, which as a result makes it possible to control the resist film so that the resist film can have a desired surface condition or a desired component distribution.

The high fluorine-containing resin preferably has, for example, the structural units A to C contained in the base resin and a structural unit represented by the following formula (6) (hereinafter, also referred to as a “structural unit G”), if necessary.

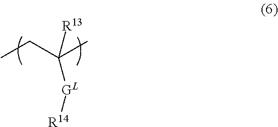

In the above formula (6), R¹³ is a hydrogen atom, a methyl group, or a trifluoromethyl group; G is a single bond, an oxygen atom, a sulfur atom, —COO—, —SO₂ONH—, —CONH—, or —OCONH—; R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit G, a hydrogen atom or a methyl group is preferred, and a methyl group is more preferred.

As G^{L} as described above, in terms of the copolymerizability of monomers resulting in the structural unit G, a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 1,1,1,3,3,3-hexafluoropropyl group and 5,5,5-trifluoro-1,1-diethylpentyl group.

When the high fluorine-containing resin has the structural unit G, the lower limit of the content of the structural unit G is preferably 10 mol %, more preferably 15 mol %, even more preferably 20 mol %, particularly preferably 25 mol % with respect to the total amount of all the structural units constituting the high fluorine-containing resin. The upper limit of the content is preferably 60 mol %, more preferably 50 mol %, even more preferably 40 mol %. When the content of the structural unit G is set to fall within the above range, the content by mass of fluorine atoms of the high fluorine-containing resin can more appropriately be adjusted to further promote the localization of the high fluorine-containing resin in the surface layer of a resist film.

The high fluorine-containing resin may have a fluorine atom-containing structural unit represented by the following formula (f-1) (hereinafter, also referred to as a “structural unit H”) in addition to the structural unit G. When the high fluorine-containing resin has the structural unit H, solubility in an alkaline developing solution is improved, and therefore generation of development defects can be prevented.

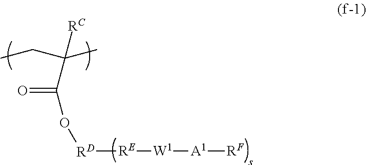

The structural unit H is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the above formula (f-1) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO— or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit H has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A1. R^{E} is a single bond, or a divalent organic group having a carbon number of 1 to 20. When s is 2 or 3, a plurality of R^{E}, W¹, A¹ and R^{F} may be each identical or different. The affinity of the high fluorine-containing resin into the alkaline developing solution can be improved by including the structural unit H having the alkali soluble group (x), and thereby prevent from generating the development defect. As the structural unit H having the alkali soluble group (x), particularly preferred is a structural unit in which A¹ is an oxygen atom and W¹ is a 1,1,1,3,3,3-hexafluoro-2,2-methanediyl group.

When the structural unit H has the alkali-dissociable group (y), R^{F} is a monovalent organic group having carbon number of 1 to 30; A¹ is an oxygen atom, —NR^{aa}—, —COO—*, or —SO₂O—*; R^{aa} is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{E} is a single bond, or a divalent organic group having a carbon number of 1 to 20. When A¹ is —COO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit H having the alkali-dissociable group (y). As a result, the affinity of the high fluorine-containing resin into the alkaline developing solution can be significantly improved, and thereby prevent from generating the development defect more efficiently. As the structural unit H having the alkali-dissociable group (y), particularly preferred is a structural unit in which A¹ is —COO—*, and R^{F} or W¹, or both is/are a fluorine atom.

In terms of the copolymerizability of monomers resulting in the structural unit H, R^{C} is preferably a hydrogen atom or a methyl group, and more preferably a methyl group.

When R^{E} is a divalent organic group, R^{E} is preferably a group having a lactone structure, more preferably a group having a polycyclic lactone structure, and further preferably a group having a norbornane lactone structure.

When the high fluorine-containing resin has the structural unit H, the lower limit of the content of the structural unit H is preferably 10 mol %, more preferably 20 mol %, even more preferably 30 mol %, particularly preferably 35 mol % with respect to the total amount of all the structural units constituting the high fluorine-containing resin. The upper limit of the content is preferably 90 mol %, more preferably 75 mol %, even more preferably 60 mol %. When the content of the structural unit H is set to fall within the above range, water repellency of a resist film during immersion exposure can further be improved.

The lower limit of Mw of the high fluorine-containing resin is preferably 1,000, more preferably 2,000, further preferably 3,000, and particularly preferably 5,000. The upper limit of Mw is preferably 50,000, more preferably 30,000, further preferably 20,000, and particularly preferably 15,000.

The lower limit of the Mw/Mn of the high fluorine-containing resin is typically 1, and more preferably 1.1. The upper limit of the Mw/Mn is typically 5, preferably 3, more preferably 2, and further preferably 1.7.

The lower limit of the content of the high fluorine-containing resin is preferably 0.1% by mass, more preferably 0.5% by mass, further preferably 1% by mass, and even further preferably 1.5% by mass based on the total solid content of the radiation-sensitive resin composition. The upper limit of the content is preferably 20% by mass, more preferably 15% by mass, further preferably 10% by mass, and particularly preferably 7% by mass.

The lower limit of the content of the high fluorine-containing resin is preferably 0.1 part by mass, more preferably 0.5 part by mass, further preferably 1 part by mass, and particularly preferably 1.5 part by mass based on 100 parts by mass of total base resins. The upper limit of the content is preferably 15 parts by mass, more preferably 10 parts by mass, further preferably 8 parts by mass, and particularly preferably 5 parts by mass.

When the content of the high fluorine-containing resin is set to fall within the above range, the high fluorine-containing resin can more effectively be localized in the surface layer of a resist film, which as a result makes it possible to further enhance the water repellency of the surface of the resist film during liquid immersion lithography. The radiation-sensitive resin composition may contain one kind of high fluorine-containing resin or two or more kinds of high fluorine-containing resins.

(Method for Synthesizing High Fluorine-Containing Resin)

The high fluorine-containing resin can be synthesized by a method similar to the above-described method for synthesizing a base resin.

### <Radiation-Sensitive Acid Generator>

The radiation-sensitive acid generator is a component that generates an acid by exposure. The radiation-sensitive acid generator is preferably represented by the following formula (p-1).

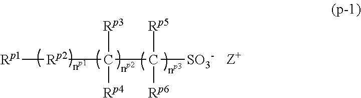

(wherein R^{p1} is a monovalent group containing a six- or higher-membered ring structure,

R^{p2} is a divalent linking group,

R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms,

R^{p5} and R^{p6} are each independently a fluorine atom or a monovalent fluorinated hydrocarbon group having 1 to 20 carbon atoms,

n^{p1} is an integer of 0 to 10, n^{p2} is an integer of 0 to 10, and n^{p3} is an integer of 0 to 10, n^{p1}+n^{p2}+n^{p3} is an integer of 1 or more and 30 or less,

when n^{p1} is 2 or more, two or more R^{p2}s are the same or different from each other,

when n^{p2} is 2 or more, two or more R^{p3}s are the same or different from each other and two or more R^{p4}s are the same or different from each other,

when n^{p3} is 2 or more, two or more R^{p5}s are the same or different and two or more R^{p6}s are the same or different, and

Z⁺ is a monovalent onium cation).

Examples of the monovalent group containing a ring structure represented by R^{p1} include a monovalent group containing a five- or higher-membered alicyclic structure, a monovalent group containing a five- or higher-membered aliphatic heterocyclic structure, a monovalent group containing a six- or higher-membered aromatic ring structure, and a monovalent group containing a six- or higher-membered aromatic heterocyclic structure.

Examples of the alicyclic structure having 5 or more ring atoms include:

monocyclic cycloalkane structures such as a cyclopentane structure, a cyclohexane structure, a cycloheptane structure, a cyclooctane structure, a cyclononane structure, a cyclodecane structure, and a cyclododecane structure;

monocyclic cycloalkene structures such as a cyclopentene structure, a cyclohexene structure, a cycloheptene structure, a cyclooctene structure, and a cyclodecene structure;

polycyclic cycloalkane structures such as a norbornane structure, an adamantane structure, a tricyclodecane structure, and a tetracyclododecane structure; and

polycyclic cycloalkene structures such as a norbornene structure and a tricyclodecene structure.

Examples of the aliphatic heterocyclic structure having 5 or more ring atoms include:

lactone structures such as a pentanolactone structure, a hexanolactone structure, and a norbornanelactone structure;

sultone structures such as a pentanosultone structure, a hexanosultone structure, and a norbornanesultone structure;

oxygen atom-containing heterocyclic structures such as an oxacyclopentane structure, an oxacycloheptane structure, and an oxanorbornane structure;

nitrogen atom-containing heterocyclic structures such as an azacyclopentane structure, an azacyclohexane structure, and diazabicyclooctane structure; and

sulfur atom-containing heterocyclic structures such as a thiacyclopentane structure, a thiacyclohexane structure, and a thianorbornane structure.

Examples of the aromatic ring structure having 6 or more ring atoms include a benzene structure, a naphthalene structure, a phenanthrene structure, and an anthracene structure.

Examples of the aromatic heterocyclic structure having 6 or more ring atoms include: oxygen atom-containing heterocyclic structures such as a furan structure, a pyran structure, and a benzopyran structure; and nitrogen atom-containing heterocyclic structures such as a pyridine structure, a pyrimidine structure, and an indole structure.

The lower limit of the number of ring atoms of the cyclic structure represented by R^{p1} may be 6, but is preferably 7, more preferably 8, even more preferably 9, particularly preferably 10. On the other hand, the upper limit of the number of ring atoms is preferably 15, more preferably 14, even more preferably 13, particularly preferably 12. When the number of ring atoms is set to fall within the above range, the diffusion length of the acid can more appropriately be reduced, which as a result makes it possible to further improve various performances of the radiation-sensitive resin composition.

Part or all of hydrogen atoms of the ring structure in R^{p1} may be substituted by a substituent. Examples of the substituent include halogen atoms such as a fluorine atom, a chlorine atom, a bromine atom, and an iodine atom, a hydroxyl group, a carboxyl group, a cyano group, a nitro group, an alkoxy group, an alkoxycarbonyl group, an alkoxycarbonyloxy group, an acyl group, and an acyloxy group. Among them, a hydroxyl group is preferred.

Among them, R^{p1} is preferably a monovalent group including an alicyclic structure having 5 or more ring atoms or a monovalent group including an aliphatic heterocyclic structure having 5 or more ring atoms, more preferably a monovalent group including an alicyclic structure having 6 or more ring atoms or a monovalent group including an aliphatic heterocyclic structure having 6 or more ring atoms, even more preferably a monovalent group including an alicyclic structure having 9 or more ring atoms or a monovalent group including an aliphatic heterocyclic structure having 9 or more ring atoms, even more preferably an adamantly group, a hydroxyadamantyl group, a norbornanelacton-yl group, a norbornanesulton-yl group, or 5-oxo-4-oxatricyclo[4.3.1.13,8]undecan-yl group, particularly preferably an adamantly group.

Examples of the divalent linking group represented by R^{p2} include a carbonyl group, an ether group, a carbonyloxy group, a sulfide group, a thiocarbonyl group, a sulfonyl group, a divalent hydrocarbon group, and a group obtained by combining two or more of these groups. The divalent linking group represented by R^{p2} is preferably a carbonyloxy group, a sulfonyl group, an alkanediyl group, or a cycloalkanediyl group, more preferably a carbonyloxy group or a cycloalkanediyl group, even more preferably a carbonyloxy group or a norbornanediyl group, particularly preferably a carbonyloxy group.

Examples of the monovalent hydrocarbon group having 1 to 20 carbon atoms represented by R^{p3} and R^{p4} include alkyl groups having 1 to 20 carbon atoms. Examples of the monovalent fluorinated hydrocarbon group having 1 to 20 carbon atoms represented by R^{p3} and R^{p4} include fluorinated alkyl groups having 1 to 20 carbon atoms. R^{p3} and R^{p4} are each preferably a hydrogen atom, a fluorine atom, or a fluorinated alkyl group, more preferably a fluorine atom or a perfluoroalkyl group, even more preferably a fluorine atom or a trifluoromethyl group.

Examples of the monovalent fluorinated hydrocarbon group having 1 to 20 carbon atoms represented by R^{p5} and R^{p6} include fluorinated alkyl groups having 1 to 20 carbon atoms. R^{p5} and R^{p6} are each preferably a fluorine atom or a fluorinated alkyl group, more preferably a fluorine atom or a perfluoroalkyl group, even more preferably a fluorine atom or a trifluoromethyl group, particularly preferably a fluorine atom.

n^{p1} is preferably an integer of 0 to 5, more preferably an integer of 0 to 3, even more preferably an integer of 0 to 2, particularly preferably 0 or 1.

n^{p2} is more preferably an integer of 0 to 2, even more preferably 0 or 1, particularly preferably 0.

n^{p3} is preferably an integer of 0 to 5, more preferably an integer of 1 to 4, even more preferably an integer of 1 to 3, particularly preferably 1 or 2. When n^{p3} is 1 or more, the strength of an acid generated from the compound represented by the above formula (p-1) can be increased, which as a result makes it possible to further improve the CDU performance or the like of the radiation-sensitive resin composition. The upper limit of n^{p3} is preferably 4, more preferably 3, even more preferably 2.

It is to be noted that in the above formula (p-1), n^{p1}+n^{p2}+n^{p3} is an integer of 1 or more and 30 or less. The lower limit of n^{p1}+n^{p2}+n^{p3} is preferably 2, more preferably 4. The upper limit of n^{p1}+n^{p2}+n^{p3} is preferably 20, more preferably 10.

An example of the monovalent onium cation represented by Z⁺ is a radioactive ray-degradable onium cation containing an element such as S, I, O, N, P, Cl, Br, F, As, Se, Sn, Sb, Te, or Bi. Examples of such a radioactive ray-degradable onium cation include a sulfonium cation, a tetrahydrothiophenium cation, an iodonium cation, a phosphonium cation, a diazonium cation, and a pyridinium cation. Among them, a sulfonium cation or an iodonium cation is preferred. The sulfonium cation or the iodonium cation is preferably represented by any of the following formulas (X-1) to (X-6).

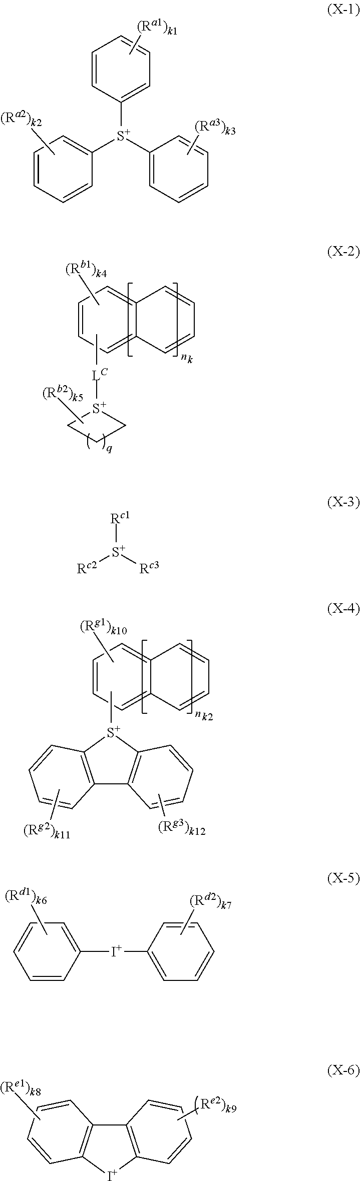

In the above formula (X-1), R^{a1}, R^{a2} and R^{a3} are each independently a substituted or unsubstituted, straight or branched chain alkyl group, alkoxy group or alkoxycarbonyloxy group having a carbon number of 1 to 12; a substituted or unsubstituted, monocyclic or polycyclic cycloalkyl group having a carbon number of 3 to 12; a substituted or unsubstituted aromatic hydrocarbon group having a carbon number of 6 to 12; a hydroxy group, a halogen atom, —OSO₂—RP, —SO₂—R^{Q} or —S—R^{T}; or a ring structure obtained by combining two or more of these groups. The ring structure may contain heteroatoms such as O and S between the carbon-carbon bonds forming the skeleton. R^{P}, R^{Q} and R^{T} are each independently a substituted or unsubstituted, straight or branched chain alkyl group having a carbon number of 1 to 12; a substituted or unsubstituted alicyclic hydrocarbon group having a carbon number of 5 to 25; and a substituted or unsubstituted aromatic hydrocarbon group having a carbon number of 6 to 12. k1, k2 and k3 are each independently an integer of 0 to 5. When there are a plurality of R^{a1} to R^{a3} and a plurality of R^{P}, R^{Q} and R^{T}, a plurality of R^{a1} to R^{a3} and a plurality of R^{P}, R^{Q} and R^{T} may be each identical or different.

In the above formula (X-2), R^{b1} is a substituted or unsubstituted, straight chain or branched alkyl group or alkoxy group having a carbon number of 1 to 20; a substituted or unsubstituted acyl group having a carbon number of 2 to 8; or a substituted or unsubstituted aromatic hydrocarbon group having a carbon number of 6 to 8; or a hydroxy group. nₖ is 0 or 1. When nₖ is 0, k4 is an integer of 0 to 4. When nₖ is 1, k4 is an integer of 0 to 7. When there are a plurality of R^{b1}, a plurality of R^{b1} may be each identical or different. A plurality of R^{b1} may represent a ring structure obtained by combining them. R^{b2} is a substituted or unsubstituted, straight chain or branched alkyl group having a carbon number of 1 to 7; or a substituted or unsubstituted aromatic hydrocarbon group having a carbon number of 6 to 7. L^{C} is a single bond or divalent linking group. k5 is an integer of 0 to 4. When there are a plurality of R^{b2}, a plurality of R^{b2} may be each identical or different. A plurality of R^{b2} may represent a ring structure obtained by combining them. q is an integer of 0 to 3. In the formula, the ring structure containing S⁺ may contain a heteroatom such as O or S between the carbon-carbon bonds forming the skeleton.

In the above formula (X-3), R^{c1}, R^{c2} and R^{c3} are each independently a substituted or unsubstituted, straight or branched chain alkyl group having a carbon number of 1 to 12.

In the above formula (X-4), R^{g1} is a substituted or unsubstituted linear or branched alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ₂ is 0, k10 is an integer of 0 to 4, and when nₖ₂ is 1, k10 is an integer of 0 to 7. When there are two or more R^{g1}s, the two or more R^{g1}s are the same or different from each other, and may represent a cyclic structure formed by combining them together. R^{g2} and R^{g3} are each independently a substituted or unsubstituted linear or branched alkyl, alkoxy, or alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, a halogen atom, or a ring structure formed by combining two or more of these groups together. K11 and k12 are each independently an integer of 0 to 4. When there are two or more R^{g2}s and two or more R^{g3}s, the two or more R^{g2}s may be the same or different from each other, and the two or more R^{g3}s may be the same or different from each other.

In the above formula (X-5), R^{d1} and R^{d2} are each independently a substituted or unsubstituted, straight or branched chain alkyl group, alkoxy group or alkoxycarbonyl group having a carbon number of 1 to 12; a substituted or unsubstituted aromatic hydrocarbon group having a carbon number of 6 to 12; a halogen atom; a halogenated alkyl group having a carbon number of 1 to 4; a nitro group; or a ring structure obtained by combining two or more of these groups. k6 and k7 are each independently an integer of 0 to 5. When there are a plurality of R^{d1} and a plurality of R^{d2}, a plurality of R^{d1} and a plurality of R^{d2} may be each identical or different.

In the above formula (X-6), R^{e1} and R^{e2} are each independently a halogen atom; a substituted or unsubstituted straight or branched chain alkyl group having a carbon number of 1 to 12; or a substituted or unsubstituted aromatic hydrocarbon group having a carbon number of 6 to 12. k8 and k9 are each independently an integer of 0 to 4.

Examples of the radiation-sensitive acid generator 1 represented by the above formula (p-1) include radiation-sensitive acid generators represented by the following formulas (p-1-1) to (p-1-35) (hereinafter, also referred to as “radiation-sensitive acid generators (p-1-1) to (p-1-35)”).

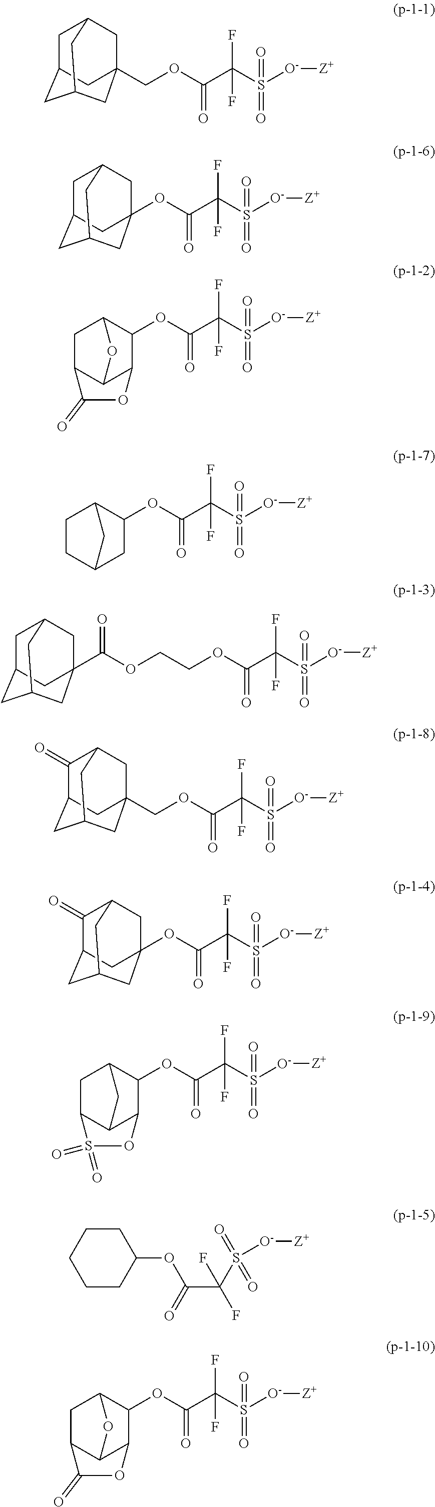

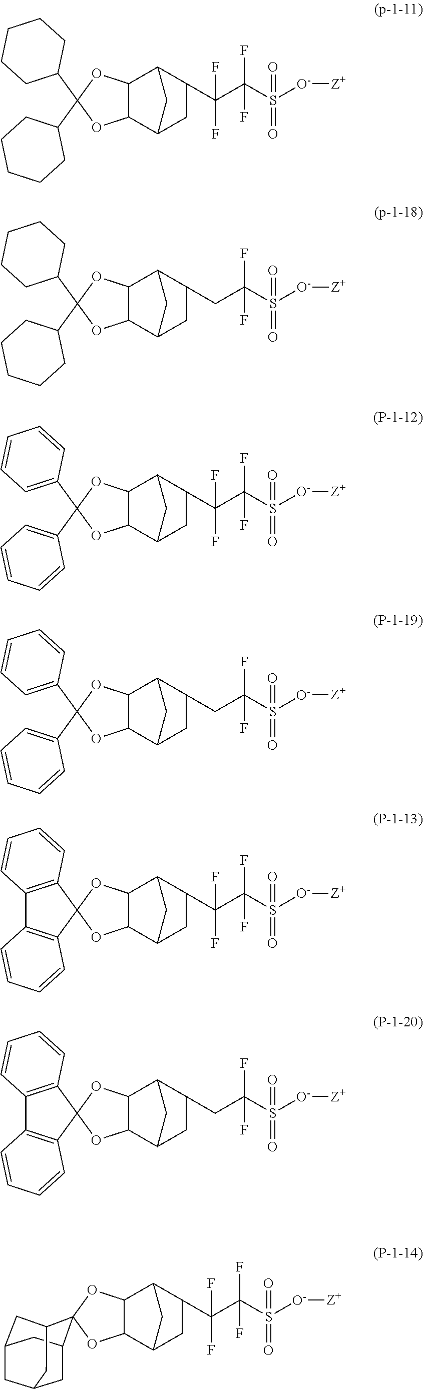

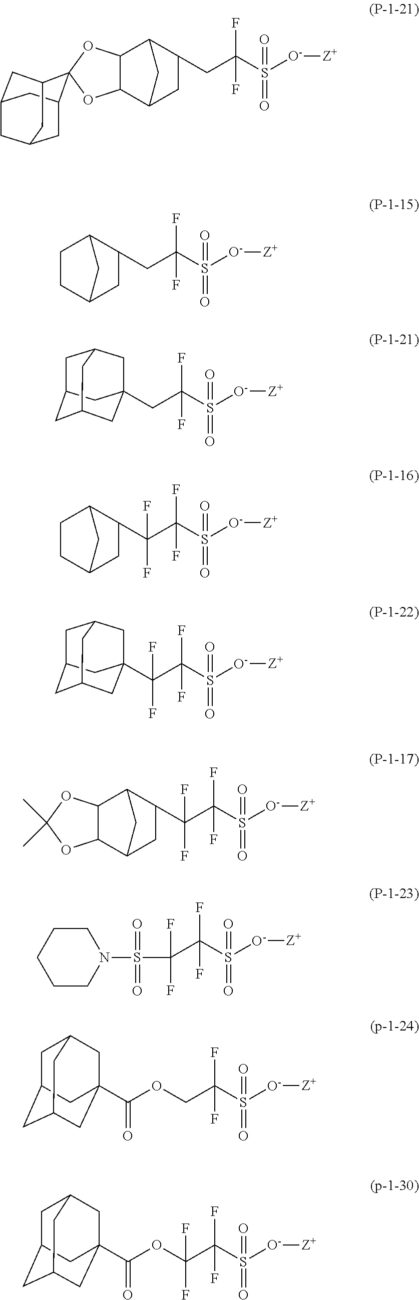

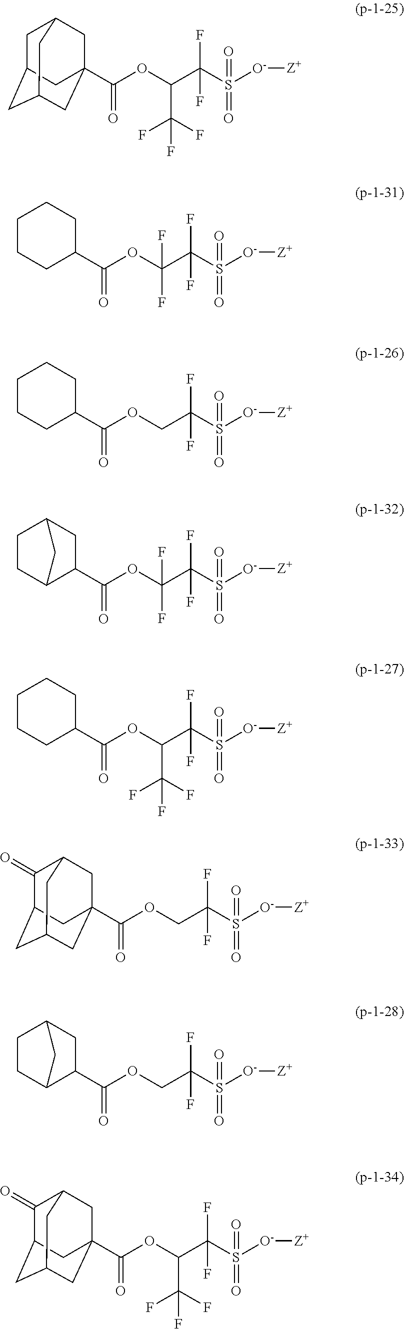

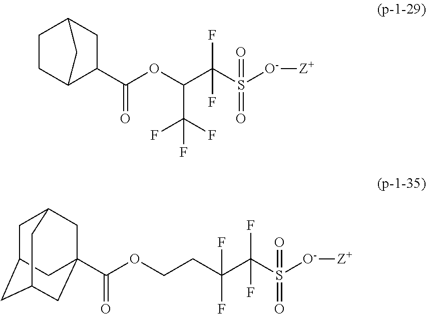

In the above formulas (p-1-1) to (p-1-35), Z⁺ is a monovalent onium cation.

Among them, radiation-sensitive acid generators represented by the above formulas (p-1-9), (p-1-13), (p-1-17), (p-1-23), (p-1-25), and (p-1-35) are preferred.

These radiation-sensitive acid generators may be used singly or in combination of two or more of them. The lower limit of the content of the radiation-sensitive acid generator is preferably 0.1 part by mass, more preferably 1 part by mass, even more preferably 5 parts by mass per 100 parts by mass of the resin. The upper limit of the content is preferably 50 parts by mass, more preferably 40 parts by mass, even more preferably 30 parts by mass. This makes it possible to exhibit excellent sensitivity, LWR performance, and process margin during resist pattern formation.

(Acid Diffusion Controlling Agent)

If necessary, the radiation-sensitive resin composition may contain an acid diffusion controlling agent. The acid diffusion controlling agent has the effect of controlling a phenomenon in which an acid generated from the radiation-sensitive acid generator by exposure diffuses in a resist film to prevent an undesired chemical reaction in an unexposed part. Further, the radiation-sensitive acid controlling agent improves the storage stability of a resulting radiation-sensitive resin composition. Further, the resolution of a resist pattern is further improved, the line width change of a resist pattern due to variation in post exposure delay time between exposure and development treatment can be prevented, and a radiation-sensitive resin composition excellent in process stability can be obtained.

Examples of the acid diffusion controlling agent include a compound represented by the following formula (7) (hereinafter, also referred to as a “nitrogen-containing compound (I)”), a compound having two nitrogen atoms in the same molecule (hereinafter, also referred to as a “nitrogen-containing compound (II)”), a compound having three nitrogen atoms (hereinafter, also referred to as a “nitrogen-containing compound (III)”), an amide group-containing compound, a urea compound, and a nitrogen-containing heterocyclic compound.

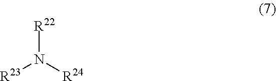

In the above formula (7), R²², R²³, and R²⁴ are each independently a hydrogen atom, a substituted or unsubstituted alkyl group, a substituted or unsubstituted cycloalkyl group, a substituted or unsubstituted aryl group, or a substituted or unsubstituted aralkyl group.

Examples of the nitrogen-containing compound (I) include: a monoalkylamine such as n-hexylamine; a dialkylamine such as di-n-butylamine; a trialkylamine such as triethylamine; and an aromatic amine such as aniline.

Examples of the nitrogen-containing compound (II) include ethylenediamine and N,N,N′,N′-tetramethylethylenediamine.

Examples of the nitrogen-containing compound (III) include: a polyamine compound such as polyethyleneimine or polyallylamine; and a polymer such as dimethylaminoethylacrylamide.

Examples of the amide group-containing compound include formamide, N-methylformamide, N,N-dimethylformamide, acetamide, N-methylacetamide, N,N-dimethylacetamide, propionamide, benzamide, pyrrolidone, and N-methylpyrrolidone.

Examples of the urea compound include methylurea, 1,1-dimethylurea, 1,3-dimethylurea, 1,1,3,3-tetramethylurea, 1,3-diphenylurea, and tributylthiourea.

Examples of the nitrogen-containing heterocyclic compound include: pyridines such as pyridine and 2-methylpyridine; morpholines such as N-propylmorpholine and N-(undecylcarbonyloxyethyl)morpholine; pyrazines; and pyrazoles.

As the nitrogen-containing organic compound, a compound having an acid-dissociable group may be used. Examples of such a nitrogen-containing compound having an acid-dissociable group include N-t-butoxycarbonyl piperidine, N-t-butoxycarbonyl imidazole, N-t-butoxycarbonyl benzimidazole, N-t-butoxycarbonyl-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, and N-t-amyloxycarbonyl-4-hydroxypiperidine.

As the acid diffusion controlling agent, an onium salt compound may appropriately be used which generates an acid having a pKa higher than that of an acid generated from the above-described radiation-sensitive acid generator (hereinafter, also referred to as a “radiation-sensitive weak acid generator” for the sake of expediency). An acid generated from the radiation-sensitive weak acid generator is a weak acid that does not induce dissociation of the acid-dissociable group under conditions where the acid-dissociable group in the resin is dissociated. It is to be noted that in this description, the term “dissociation” of the acid-dissociable group means that the acid-dissociable group is dissociated by post-exposure bake at 110° C. for 60 seconds.

Examples of the radiation-sensitive weak acid generator include a sulfonium salt compound represented by the following formula (8-1) and an iodonium salt compound represented by the following formula (8-2).

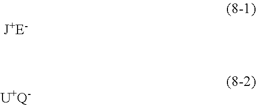

In the above formulas (8-1) and (8-2), J⁺ is a sulfonium cation, and U⁺ is an iodonium cation. Examples of the sulfonium cation represented by J+ include sulfonium cations represented by the above formulas (X-1) to (X-4). Examples of the iodonium cation represented by U⁺ include iodonium cations represented by the above formulas (X-5) to (X-6). E⁻ and Q⁻ are each independently an anion represented by OH⁻, R^{α}—COO⁻, or R^{α}—SO₃⁻. R^{α} is an alkyl group, an aryl group, or an aralkyl group. The hydrogen atom of the alkyl group represented by R^{a} or the hydrogen atom of aromatic ring of the aryl group or the aralkyl group may be substituted by a halogen atom, a hydroxyl group, a nitro group, a halogen atom-substituted or unsubstituted alkyl group having 1 to 12 carbon atoms, or a halogen atom-substituted or unsubstituted alkoxy group having 1 to 12 carbon atoms.

Examples of the radiation-sensitive weak acid generator include compounds represented by the following formulas.

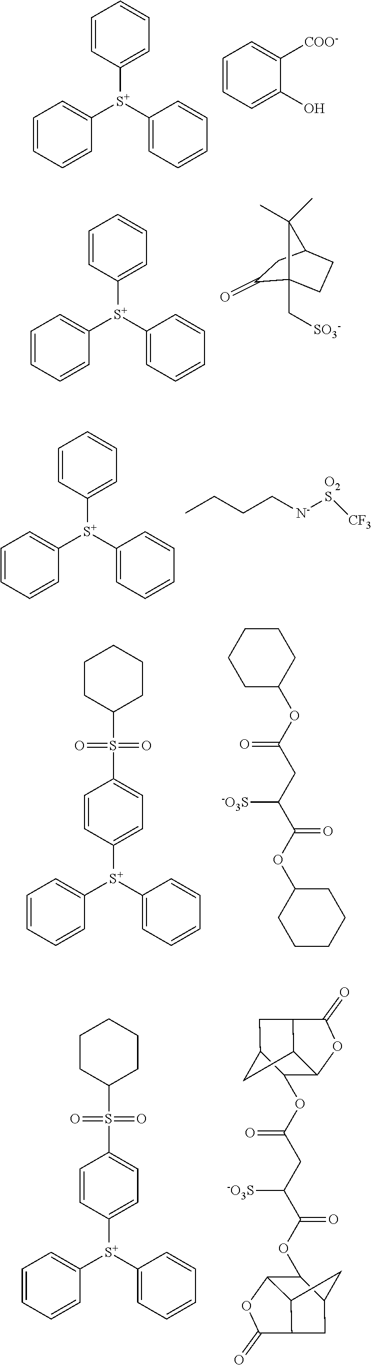

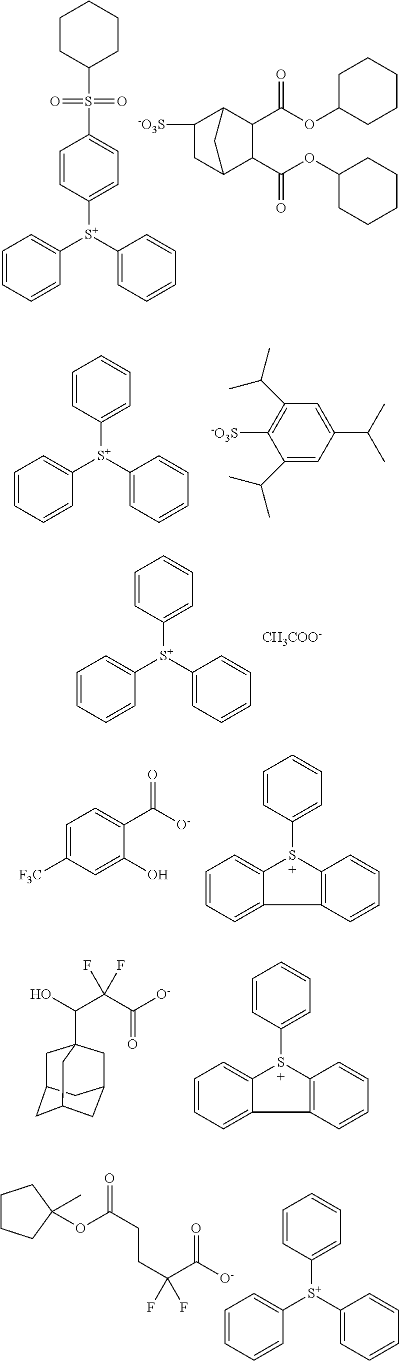

The lower limit of the content of the acid diffusion controlling agent is preferably 5 mol %, more preferably 10 mol %, even more preferably 15 mol % with respect to the total number of moles of the radiation-sensitive acid generator. The upper limit of the content is preferably 40 mol %, more preferably 30 mol %, even more preferably 25 mol %. When the content of the acid diffusion controlling agent is set to fall within the above range, the lithography performance of the radiation-sensitive resin composition can further be improved. The radiation-sensitive resin composition may contain one or two or more kinds of acid diffusion controlling agents.

<Solvent>

The radiation-sensitive resin composition according to the present embodiment contains a solvent. The solvent is not particularly limited as long as it can dissolve or disperse at least the resin, the radiation-sensitive acid generator, and an additive or the like contained if necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:

a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;

a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and

a partially etherized polyhydric alcohol-based solvent in which a part of hydroxy groups in the polyhydric alcohol-based solvent is etherized.

Examples of the ether-based solvent include:

a dialkyl ether-based solvent, including diethyl ether, dipropyl ether, and dibutyl ether;

a cyclic ether-based solvent, including tetrahydrofuran and tetrahydropyran;

an ether-based solvent having an aromatic ring, including diphenylether and anisole (methyl phenyl ether); and

an etherized polyhydric alcohol-based solvent in which a hydroxy group in the polyhydric alcohol-based solvent is etherized.

Examples of the ketone-based solvent include:

a chain ketone-based solvent, including acetone, butanone, and methyl-iso-butyl ketone;

a cyclic ketone-based solvent, including cyclopentanone, cyclohexanone, and methylcyclohexanone; and

2,4-pentanedione, acetonylacetone, and acetophenone.

Examples of the amide-based solvent include:

a cyclic amide-based solvent, including N,N′-dimethyl imidazolidinone and N-methylpyrrolidone; and

a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:

a monocarboxylate ester-based solvent, including n-butyl acetate and ethyl lactate;

a partially etherized polyhydric alcohol acetate-based solvent, including diethylene glycol mono-n-butyl ether acetate, propylene glycol monomethyl ether acetate, and dipropylene glycol monomethyl ether acetate;

a lactone-based solvent, including γ-butyrolactone and valerolactone;

a carbonate-based solvent, including diethyl carbonate, ethylene carbonate, and propylene carbonate; and

a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:

an aliphatic hydrocarbon-based solvent, including n-hexane, cyclohexane, and methylcyclohexane;

an aromatic hydrocarbon-based solvent, including benzene, toluene, di-iso-propylbenzene, and n-amylnaphthalene.

Among them, the ester-based solvent or the ketone-based solvent is preferred. The partially etherized polyhydric alcohol acetate-based solvent, the cyclic ketone-based solvent, or the lactone-based solvent is more preferred. Propylene glycol monomethyl ether acetate, cyclohexanone, or γ-butyrolactone is still more preferred. The radiation-sensitive resin composition may include one type of the solvent, or two or more types of the solvents in combination.

<Other Optional Components>

The radiation-sensitive resin composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them.

(Cross-Linking Agent)

The cross-linking agent is a compound having two or more functional groups. The cross-linking agent causes a cross-linking reaction in a polymer component (1) by an acid catalytic reaction in a baking step after a one-shot exposure step to increase the molecular weight of the polymer component (1) so that the solubility of a pattern-exposed part in a developer is reduced. Examples of the functional group include a (meth)acryloyl group, a hydroxymethyl group, an alkoxymethyl group, an epoxy group, and a vinyl ether group.

(Localization Enhancing Agent)

The localization enhancing agent has an effect of localizing the high fluorine-containing resin on the surface of the resist film more effectively. The added amount of the high fluorine-containing resin can be decreased compared to the traditionally added amount by including the localization enhancing agent in the radiation-sensitive resin composition. The localization enhancing agent can further prevent from eluting the ingredient of the composition from the resist film to an immersion medium and carry out the immersion exposure at higher speed with a high-speed scan, while maintaining the lithography properties of the radiation-sensitive resin composition. As a result, the hydrophobicity of the surface of the resist film can be improved, resulting in the prevention of the defect due to the immersion, for example, the watermark defect. Example of the compound which may be used as the localization enhancing agent includes a low molecular weight compound having a specific dielectric constant of not less than 30 and not more than 200 and a boiling point of 100° C. or more at 1 atm. Specific examples of the compound include a lactone compound, a carbonate compound, a nitrile compound, and a polyhydric alcohol.

Examples of the lactone compound include γ-butyrolactone, valerolactone, mevalonic lactone, and norbornane lactone.

Examples of the carbonate compound include propylene carbonate, ethylene carbonate, butylene carbonate, and vinylene carbonate.

Examples of the nitrile compound include succinonitrile.

Examples of the polyhydric alcohol include glycerin.

The lower limit of the content of the localization enhancing agent is preferably 10 parts by mass, more preferably 15 parts by mass, still more preferably 20 parts by mass, and yet still more preferably 25 parts by mass, with respect to 100 parts by mass of the total amount of the resin in the radiation-sensitive resin composition. The upper limit of the content is preferably 300 parts by mass, more preferably 200 parts by mass, still more preferably 100 parts by mass, and particularly preferably 80 parts by mass. The radiation-sensitive resin composition may contain one or two or more of localization enhancing agents.

(Surfactant)

The surfactant has an effect of improving the coating properties, the striation, and the developability of the composition. Examples of the surfactant include a nonionic surfactant, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the surfactant which is commercially available include KP341 (manufactured by Shin-Etsu Chemical Co., Ltd.), POLYFLOW No. 75, POLYFLOW No. 95 (all manufactured by Kyoeisha Chemical Co., Ltd.), EFTOP EF301, EFTOP EF303, EFTOP EF352 (all manufactured by Tokem Products), Megafac F171, Megafac F173 (all manufactured by DIC), Fluorad FC430, Fluorad FC431 (all manufactured by Sumitomo 3M Limited.), AsahiGuard AG710, Surflon S-382, Surflon SC-101, Surflon SC-102, Surflon SC-103, Surflon SC-104, Surflon SC-105, Surflon SC-106 (all manufactured by Asahi Glass Co., Ltd.). The content of the surfactant in the radiation-sensitive resin composition is typically not more than 2 parts by mass based on 100 parts by mass of total resins.

(Alicyclic Backbone-Containing Compound)

The alicyclic backbone-containing compound has an effect of improving the dry etching resistance, the shape of the pattern, the adhesiveness between the substrate, and the like.

Examples of the alicyclic backbone-containing compound include:

adamantane derivatives, including 1-adamantane carboxylic acid, 2-adamantanone, and t-butyl 1-adamantane carboxylate;

deoxycholic acid esters, including t-butyl deoxycholate, t-butoxycarbonylmethyl deoxycholate, and 2-ethoxyethyl deoxycholate;

lithocholic acid esters, including t-butyl lithocholate, t-butoxycarbonylmethyl lithocholate, and 2-ethoxyethyl lithocholate; and

3-[2-hydroxy-2,2-bis(trifluoromethyl)ethyl]tetracyclo[4.4.0.1(2,5).1(7,10)]d odecane, and 2-hydroxy-9-methoxycarbonyl-5-oxo-4-oxa-tricyclo[4.2.1.0(3,7)]nonane. The content of the alicyclic backbone-containing compound in the radiation-sensitive resin composition is typically not more than 5 parts by mass based on 100 parts by mass of total resins.

(Sensitizer)

The sensitizer has the function of increasing the amount of an acid generated from the radiation-sensitive acid generator or the like, and is effective at improving “apparent sensitivity” of the radiation-sensitive resin composition.

Examples of the sensitizer include carbazoles, acetophenones, benzophenones, naphthalenes, phenols, biacetyl, eosin, rose bengal, pyrenes, anthracenes, and phenothiazines. These sensitizers may be used singly or in combination of two or more of them. The content of the sensitizer in the radiation-sensitive resin composition is usually 2 parts by mass or less per 100 parts by mass of the resin.

<Method for Preparing Radiation-Sensitive Resin Composition>

The radiation-sensitive resin composition can be prepared by, for example, mixing the resin, the radiation-sensitive acid generator, and optionally the high fluorine-containing resin, the solvent added in a predetermined ratio. The radiation-sensitive resin composition is preferably filtered through, for example, a filter having a pore diameter of about 0.05 μm to 0.20 μm after mixing. The solid matter concentration of the radiation-sensitive resin composition is usually 0.1 mass % to 50 mass %, preferably 0.5 mass % to 30 mass %, more preferably 1 mass % to 20 mass %.

<<Method for Forming Resist Pattern>>

A method for forming a resist pattern according to the present embodiment includes:

(1) forming a resist film from the radiation-sensitive resin composition (hereinafter, also referred to as a “resist film-forming step”);

(2) exposing the resist film (hereinafter, also referred to as an “exposure step”); and

(3) developing the exposed resist film (hereinafter, also referred to as a “development step”).

The method for forming a resist pattern uses the above-described radiation-sensitive resin composition excellent in sensitivity in the exposure step, CDU performance, and resolution, and therefore a high-quality resist pattern can be formed. Hereinbelow, each of the steps will be described.

[Resist Film Forming Step]

In this step (the above mentioned step (1)), a resist film is formed with the radiation-sensitive resin composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 140° C., and preferably from 80° C. to 120° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-containing resin in the radiation-sensitive resin composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the exposure step, which is the next step, is performed with radiation having a wavelength of 50 nm or less, it is preferable to use a resin having, if necessary, a structural unit B together with the structural unit A as the base resin in the composition.

[Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and y ray; an electron beam; and a charged particle radiation such as a ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

[Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ester-based solvent or a ketone-based solvent is preferred. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinbelow, the present invention will specifically be described on the basis of examples, but the present invention is not limited to these examples. Methods for measuring various physical property values will be shown below.

### [Measurement of Weight Average Molecular Weight (Mw), Number Average Molecular Weight (Mn), and Dispersity (Mw/Mn)]

Measurement was performed under the measurement conditions described in the section of Resin. Dispersity (Mw/Mn) was calculated from results of the measured Mw and Mn.

[¹H-NMR Analysis and ¹³C-NMR Analysis]

Measurement was performed with use of “JNM-Delta 400” manufactured by JEOL Ltd.

### <Synthesis of Resins>

Monomers used for synthesis of resins in Examples and Comparative Examples are shown below. In the following synthesis examples, part(s) by mass refers to a value per 100 parts by mass of the total mass of monomers used, and mol % refers to a value per 100 mol % of the total number of moles of monomers used, unless otherwise specified. The present invention is not limited to the following structural units.

Among the monomers used in the synthesis of the resin in each Example, the structures of the monomers giving the structural unit represented by the formula (1) (that is, the structural unit A) are shown below.

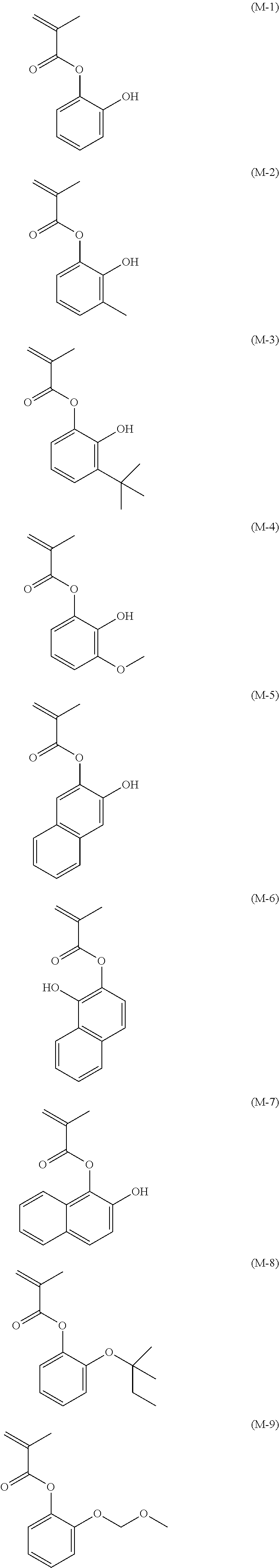

Among the monomers used in the synthesis of the resin in each Example and each Comparative Example, the structures of the monomers other than the monomers giving the structural unit A are shown below.

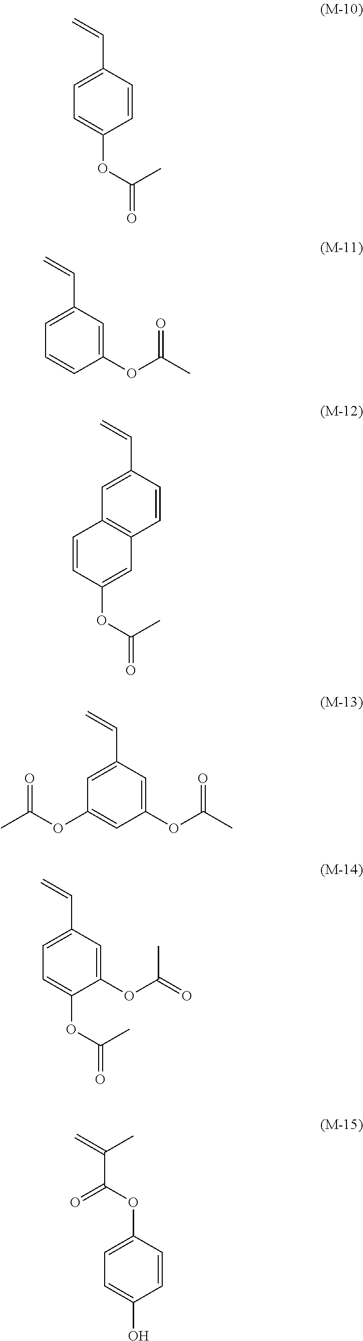

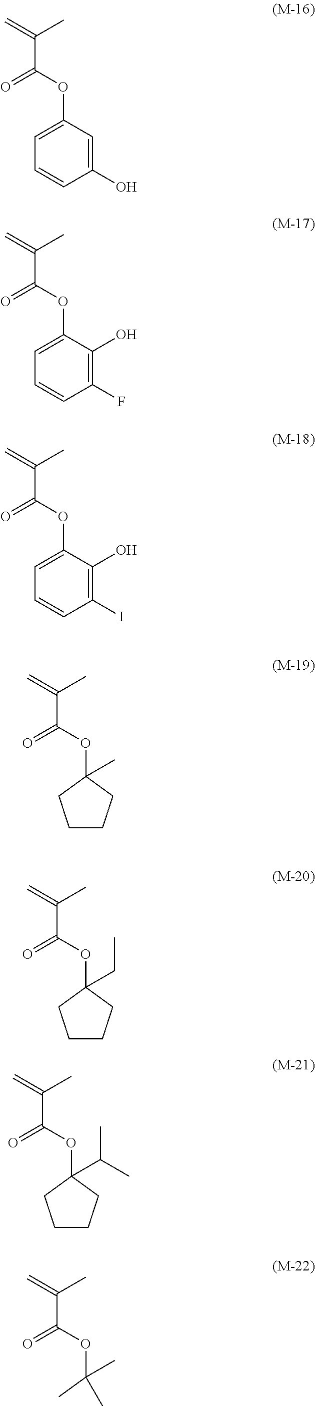

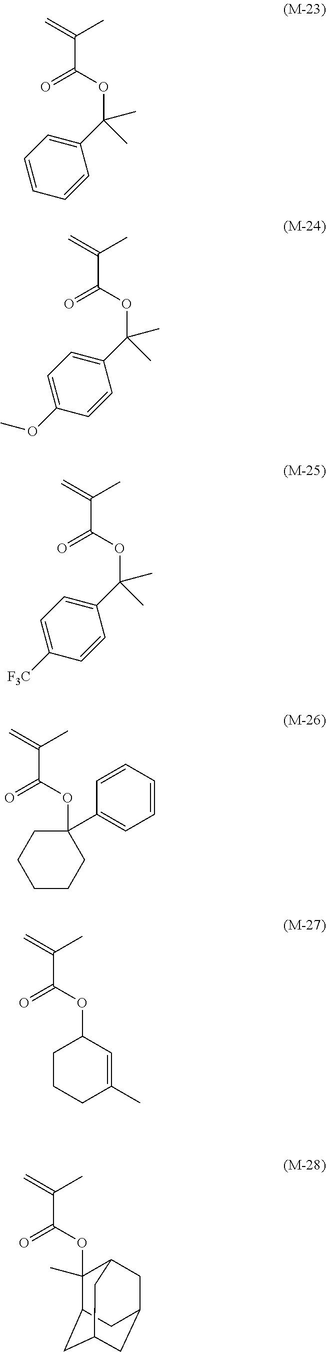

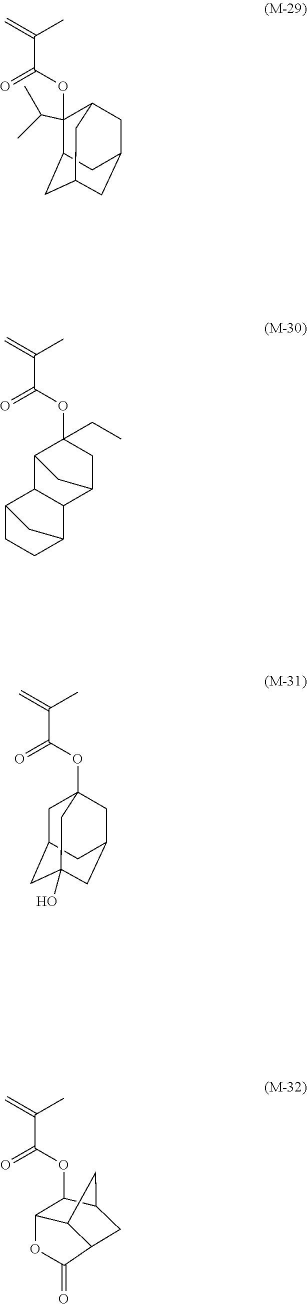

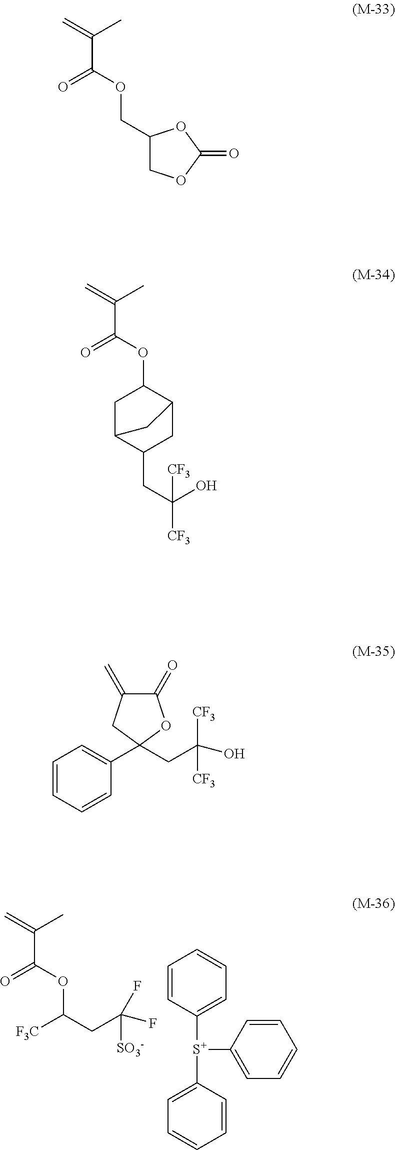

### (Synthesis of Monomer (M-1))

A monomer (M-1) giving the structural unit A was synthesized according to the following scheme.

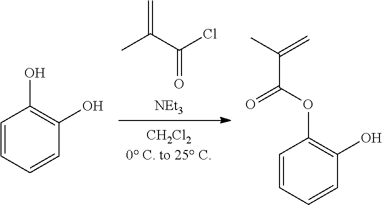

In a 3-L recovery flask, 200 g (1.816 mol) of catechol and 91.89 g (0.908 mol) of triethylamine were weighed and dissolved in dichloromethane (1500 mL). A solvent was cooled to 0° C., and 94.93 g (0.908 mol) of methacryloyl chloride was then added dropwise at a rate not exceeding 25° C. After the completion of the dropwise addition, the mixture was stirred at 25° C. for 1.5 hours. After the completion of the reaction, the reaction was quenched with a saturated aqueous solution of ammonium chloride, and extracted with methylene chloride. The residue obtained by concentration under reduced pressure was purified by column chromatography to obtain 65.08 g (yield: 20%) of a monomer (M-1).

Other monomers (M-2) to (M-9) to give the structural unit A were also synthesized in the same manner as the method for synthesizing the monomer (M-1) except that the precursor was appropriately changed.

### Synthesis Example 1

(Synthesis of Resin (A-1))

The monomer (M-1), the monomer (M-10), and the monomer (M-19) were dissolved in 1-methoxy-2-propanol (200 parts by mass with respect to the total monomer amount) at a molar ratio of 10/30/60. Next, 6 mol % of AIBN as an initiator was added with respect to the total amount of the monomers to prepare a monomer solution. Meanwhile, 1-methoxy-2-propanol (100 parts by mass with respect to the total amount of monomers) was added to an empty reaction vessel, and was heated to 85° C. while being stirred. Next, the monomer solution prepared above was added dropwise over 3 hours, and then the mixture was heated at 85° C. for another 3 hours to perform a polymerization reaction for 6 hours in total. After the completion of the polymerization reaction, the polymerization solution was cooled to room temperature. The cooled polymerization solution was charged into hexane (500 parts by mass with respect to the polymerization solution), and a precipitated white powder was separated by filtration. The white powder separated by filtration was washed twice with 100 parts by mass of hexane relative to the polymerization solution, then separated by filtration, and dissolved in 1-methoxy-2-propanol (300 parts by mass). Next, methanol (500 parts by mass), triethylamine (50 parts by mass) and ultrapure water (10 parts by mass) were added, and a hydrolysis reaction was performed at 70° C. for 6 hours with stirring. After the completion of the reaction, the remaining solvent was distilled off, and the resulting solid was dissolved in acetone (100 parts by mass). The resulting solution was added dropwise into 500 parts by mass of water to permit the coagulation of the resin. The resulting solid was separated by filtration. The solid was dried at 50° C. for 12 hours to synthesize a white powdery resin ((A-1).

### Synthesis Examples 2 to 30, 33 to 36, and 38 to 42

(Synthesis of Resin (A-2) to Resin (A-39))

Resins (A-2) to (A-39) were synthesized in the same manner as in Synthesis Example 1 except that the monomers of types shown in Table 1 were blended in a predetermined amount. The Mw and Mw/Mn of each of the resulting resins, and the content rate of the structural unit derived from each of the monomers in each of the resins are shown together in Table 1.

### Synthesis Example 31

(Synthesis of Resin (B-1))

The monomer (M-1), the monomer (M-21), and the monomer (M-32) were dissolved in 2-butanone (200 parts by mass with respect to the total monomer amount) at a molar ratio of 40/45/15. 6 mol % of AIBN as an initiator was added with respect to the total of the monomers to prepare a monomer solution. Meanwhile, 2-butanone (100 parts by mass) was added to an empty reaction vessel, and was heated to 80° C. while being stirred. Next, the monomer solution prepared above was added dropwise over 3 hours, and then the mixture was heated at 80° C. for another 3 hours to perform a polymerization reaction for 6 hours in total. After the completion of the polymerization reaction, the polymerization solution was cooled to room temperature. The cooled polymerization solution was charged into methanol (2000 parts by mass with respect to the polymerization solution), and a precipitated white powder was separated by filtration. The resulting solid was dissolved in acetone (100 parts by mass). The resulting solution was added dropwise into 500 parts by mass of water to permit the coagulation of the resin. The resulting solid was separated by filtration. The solid was dried at 50° C. for 12 hours to synthesize a white powdery resin (B-1).

### Synthesis Examples 32 and 37

(Synthesis of Polymers (B-2) and (B-3))

Resins (B-2) and (B-3) were obtained in the same manner as in Synthesis Example 31 except that monomers of types shown in Table 1 were blended in a predetermined amount. The Mw and Mw/Mn of each of the resulting resins, and the content rate of the structural unit derived from each of the monomers in each of the resins are shown together in Table 1.

TABLE 1

| | | Monomer to Give Each Structural Unit | | | | | | | | | | | |
|---|---|---|---|---|---|---|---|---|---|---|---|---|---|
| | | Structural Unit A | | Structural Unit B | | | | Structural Unit C | | Structural Units D AND E | | | |
| | | | Content | | Content | | Content | | Content | | Content | Physical | |
| | | | Rate | | Rate | | Rate | | Rate | | Rate | Property Value | |
| | Resin | Type | (mol %) | Type | (mol %) | Type | (mol %) | Type | (mol %) | Type | (mol %) | Mw | Mw/Mn |
| Synthesis | A-1 | M-1 | 10 | M-19 | 60 | — | — | M-10 | 30 | — | — | 7800 | 1.57 |
| Example 1 | | | | | | | | | | | | | |
| Synthesis | A-2 | M-1 | 20 | M-19 | 60 | — | — | M-10 | 20 | — | — | 7600 | 1.49 |
| Example 2 | | | | | | | | | | | | | |
| Synthesis | A-3 | M-1 | 30 | M-19 | 60 | — | — | M-10 | 10 | — | — | 7900 | 1.54 |
| Example 3 | | | | | | | | | | | | | |
| Synthesis | A-4 | M-2 | 30 | M-19 | 60 | — | — | M-10 | 10 | — | — | 6900 | 1.53 |
| Example 4 | | | | | | | | | | | | | |
| Synthesis | A-5 | M-3 | 25 | M-19 | 60 | — | — | M-10 | 15 | — | — | 6400 | 1.55 |
| Example 5 | | | | | | | | | | | | | |
| Synthesis | A-6 | M-4 | 20 | M-19 | 60 | — | — | M-10 | 20 | — | — | 7200 | 1.58 |
| Example 6 | | | | | | | | | | | | | |
| Synthesis | A-7 | M-5 | 15 | M-20 | 60 | — | — | M-10 | 25 | — | — | 7500 | 1.63 |
| Example 7 | | | | | | | | | | | | | |
| Synthesis | A-8 | M-6 | 15 | M-20 | 60 | — | — | M-10 | 25 | — | — | 8300 | 1.56 |
| Example 8 | | | | | | | | | | | | | |
| Synthesis | A-9 | M-7 | 15 | M-21 | 60 | — | — | M-10 | 25 | — | — | 6800 | 1.59 |
| Example 9 | | | | | | | | | | | | | |
| Synthesis | A-10 | M-8 | 15 | M-21 | 60 | — | — | M-10 | 25 | — | — | 6600 | 1.51 |
| Example 10 | | | | | | | | | | | | | |
| Synthesis | A-11 | M-9 | 15 | M-21 | 60 | — | — | M-10 | 25 | — | — | 6900 | 1.58 |
| Example 11 | | | | | | | | | | | | | |
| Synthesis | A-12 | M-1 | 20 | M-19 | 60 | — | — | M-11 | 20 | — | — | 7200 | 1.66 |
| Example 12 | | | | | | | | | | | | | |
| Synthesis | A-13 | M-1 | 20 | M-19 | 60 | — | — | M-12 | 20 | — | — | 6500 | 1.54 |
| Example 13 | | | | | | | | | | | | | |
| Synthesis | A-14 | M-1 | 25 | M-19 | 55 | — | — | M-13 | 20 | — | — | 7600 | 1.48 |
| Example 14 | | | | | | | | | | | | | |
| Synthesis | A-15 | M-1 | 10 | M-19 | 65 | — | — | M-14 | 25 | — | — | 7700 | 1.47 |
| Example 15 | | | | | | | | | | | | | |
| Synthesis | A-16 | M-1 | 30 | M-19 | 50 | — | — | M-10 | 20 | — | — | 6600 | 1.51 |
| Example 16 | | | | | | | | | | | | | |
| Synthesis | A-17 | M-1 | 30 | M-19 | 40 | — | — | M-10 | 30 | — | — | 6200 | 1.53 |
| Example 17 | | | | | | | | | | | | | |
| Synthesis | A-18 | M-1 | 25 | M-22 | 60 | — | — | M-10 | 15 | — | — | 7600 | 1.54 |
| Example 18 | | | | | | | | | | | | | |
| Synthesis | A-19 | M-1 | 25 | M-23 | 55 | — | — | M-10 | 20 | — | — | 8300 | 1.61 |
| Example 19 | | | | | | | | | | | | | |
| Synthesis | A-20 | M-1 | 25 | M-24 | 55 | — | — | M-10 | 20 | — | — | 8100 | 1.64 |
| Example 20 | | | | | | | | | | | | | |
| Synthesis | A-21 | M-1 | 25 | M-25 | 55 | — | — | M-10 | 20 | — | — | 7700 | 1.58 |
| Example 21 | | | | | | | | | | | | | |
| Synthesis | A-22 | M-1 | 25 | M-26 | 50 | — | — | M-10 | 25 | — | — | 7400 | 1.63 |
| Example 22 | | | | | | | | | | | | | |
| Synthesis | A-23 | M-1 | 25 | M-27 | 55 | — | — | M-10 | 20 | — | — | 7800 | 1.56 |
| Example 23 | | | | | | | | | | | | | |
| Synthesis | A-24 | M-1 | 25 | M-26 | 50 | — | — | M-10 | 25 | — | — | 9200 | 1.62 |
| Example 24 | | | | | | | | | | | | | |
| Synthesis | A-25 | M-1 | 25 | M-26 | 50 | — | — | M-10 | 25 | — | — | 5500 | 1.51 |
| Example 25 | | | | | | | | | | | | | |
| Synthesis | A-26 | M-1 | 25 | M-26 | 50 | — | — | M-10 | 25 | — | — | 3200 | 1.48 |
| Example 26 | | | | | | | | | | | | | |
| Synthesis | A-27 | M-1 | 20 | M-19 | 50 | M-28 | 10 | M-10 | 20 | — | — | 7600 | 1.53 |
| Example 27 | | | | | | | | | | | | | |
| Synthesis | A-28 | M-1 | 20 | M-19 | 50 | M-29 | 10 | M-10 | 20 | — | — | 8100 | 1.51 |
| Example 28 | | | | | | | | | | | | | |
| Synthesis | A-29 | M-1 | 20 | M-19 | 50 | M-30 | 10 | M-10 | 20 | — | — | 7900 | 1.55 |
| Example 29 | | | | | | | | | | | | | |
| Synthesis | A-30 | M-1 | 20 | M-19 | 60 | — | — | M-10 | 10 | M-31 | 30 | 8400 | 1.49 |
| Example 30 | | | | | | | | | | | | | |
| Synthesis | B-1 | M-1 | 40 | M-21 | 45 | — | — | — | — | M-32 | 15 | 7300 | 1.46 |
| Example 31 | | | | | | | | | | | | | |
| Synthesis | B-2 | M-1 | 40 | M-21 | 45 | — | — | — | — | M-33 | 15 | 7500 | 1.44 |
| Example 32 | | | | | | | | | | | | | |
| Synthesis | A-31 | M-1 | 20 | M-19 | 50 | — | — | M-10 | 20 | M-34 | 30 | 8200 | 1.46 |
| Example 33 | | | | | | | | | | | | | |
| Synthesis | A-32 | M-1 | 20 | M-19 | 50 | — | — | M-10 | 20 | M-35 | 30 | 8100 | 1.49 |
| Example 34 | | | | | | | | | | | | | |
| Synthesis | A-33 | M-1 | 10 | M-19 | 60 | — | — | M-10 | 30 | — | — | 18900 | 1.65 |
| Example 35 | | | | | | | | | | | | | |
| Synthesis | A-34 | M-1 | 10 | M-19 | 60 | — | — | M-10 | 30 | — | — | 12700 | 1.65 |
| Example 36 | | | | | | | | | | | | | |
| Synthesis | B-3 | M-1 | 35 | M-21 | 50 | — | — | — | — | M-36 | 15 | 7800 | 1.98 |
| Example 37 | | | | | | | | | | | | | |
| Synthesis | A-35 | — | — | M-19 | 60 | — | — | M-10 | 40 | — | — | 8200 | 1.55 |
| Example 38 | | | | | | | | | | | | | |
| Synthesis | A-36 | M-15 | 30 | M-21 | 50 | — | — | M-10 | 20 | — | — | 7700 | 1.58 |
| Example 39 | | | | | | | | | | | | | |
| Synthesis | A-37 | M-16 | 30 | M-21 | 50 | — | — | M-10 | 20 | — | — | 7100 | 1.55 |
| Example 40 | | | | | | | | | | | | | |
| Synthesis | A-38 | M-17 | 15 | M-20 | 60 | — | — | M-10 | 25 | — | — | 6800 | 1.47 |
| Example 41 | | | | | | | | | | | | | |
| Synthesis | A-39 | M-18 | 15 | M-20 | 60 | — | — | M-10 | 25 | — | — | 7600 | 1.67 |
| Example 42 | | | | | | | | | | | | | |

### <Preparation of Radiation-Sensitive Resin Composition>

Radiation-sensitive acid generators, acid diffusion controlling agents, and solvents constituting radiation-sensitive resin compositions are shown below.

### (Radiation-Sensitive Acid Generators)

C-1 to C-9: Compounds Represented by the Formulas (C-1) to (C-9)

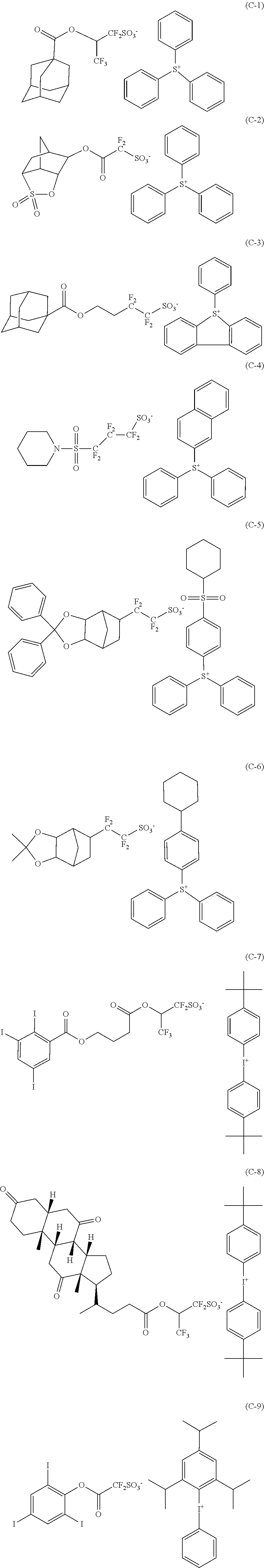

### (Acid Diffusion Controlling Agents)

D-1 to D-9: Compounds Represented by the Formulas (D-1) to (D-9)

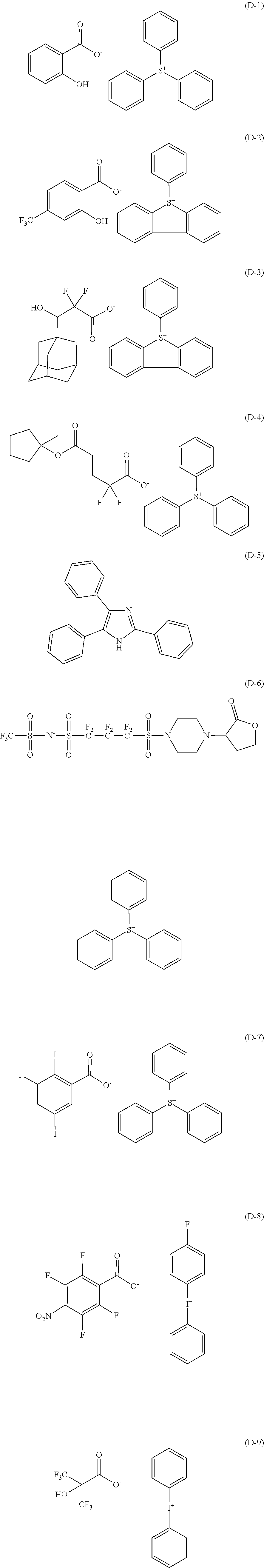

### (Solvents)

E-1: Propylene Glycol Monomethyl Ether Acetate

E-2: Propylene Glycol 1-Monomethyl Ether

### Example 1

100 parts by mass of the resin (A-1), 20 parts by mass of (B-1) as the radiation-sensitive acid generator, (D-1) as the acid diffusion controlling agent in an amount of 20 mol % with respect to the amount of (C-1), 4800 parts by mass of (E-1) and 2000 parts by mass of (E-2) as the solvent were blended. Then, the obtained mixture was filtered through a membrane filter having a pore diameter of 0.20 μm to prepare a radiation-sensitive resin composition (R-1).

### Examples 2 to 55 and Comparative Examples 1 to 5

Radiation-sensitive resin compositions (R-2) to (R-55) and (CR-1) to (CR-5) were prepared in the same manner as in Example 1 except that the type and amount of each component used were changed as shown in the following Table 2.

TABLE 2

| | Radiation- | | | Radiation- | | Acid | mol % Relative | | |
|---|---|---|---|---|---|---|---|---|---|
| | Sensitive | | | Sensitive | | Diffusion | to Radiation- | | |
| | Resin | | Parts by | Acid | Parts by | Controlling | Sensitive Acid | | Parts by |
| | Composition | Resin | Mass | Generator | Mass | Agent | Generator | Solvent | Mass |
| Example 1 | R-1 | A-1 | 100 | C-1 | 20 | D-1 | 20 | E-1/E-2 | 4800/2000 |
| Example 2 | R-2 | A-2 | 100 | C-1 | 20 | D-1 | 20 | E-1/E-2 | 4800/2000 |
| Example 3 | R-3 | A-3 | 100 | C-1 | 20 | D-1 | 20 | E-1/E-2 | 4800/2000 |
| Example 4 | R-4 | A-4 | 100 | C-1 | 20 | D-1 | 20 | E-1/E-2 | 4800/2000 |
| Example 5 | R-5 | A-5 | 100 | C-1 | 20 | D-1 | 20 | E-1/E-2 | 4800/2000 |
| Example 6 | R-6 | A-6 | 100 | C-1 | 20 | D-1 | 20 | E-1/E-2 | 4800/2000 |
| Example 7 | R-7 | A-7 | 100 | C-1 | 20 | D-1 | 20 | E-1/E-2 | 4800/2000 |
| Example 8 | R-8 | A-8 | 100 | C-1 | 20 | D-1 | 20 | E-1/E-2 | 4800/2000 |
| Example 9 | R-9 | A-9 | 100 | C-1 | 20 | D-1 | 20 | E-1/E-2 | 4800/2000 |
| Example 10 | R-10 | A-10 | 100 | C-1 | 20 | D-1 | 20 | E-1/E-2 | 4800/2000 |
| Example 11 | R-11 | A-11 | 100 | C-1 | 20 | D-1 | 20 | E-1/E-2 | 4800/2000 |
| Example 12 | R-12 | A-12 | 100 | C-1 | 20 | D-1 | 20 | E-1/E-2 | 4800/2000 |
| Example 13 | R-13 | A-13 | 100 | C-1 | 20 | D-1 | 20 | E-1/E-2 | 4800/2000 |
| Example 14 | R-14 | A-14 | 100 | C-1 | 20 | D-1 | 20 | E-1/E-2 | 4800/2000 |
| Example 15 | R-15 | A-15 | 100 | C-1 | 20 | D-1 | 20 | E-1/E-2 | 4800/2000 |
| Example 16 | R-16 | A-16 | 100 | C-1 | 20 | D-1 | 20 | E-1/E-2 | 4800/2000 |
| Example 17 | R-17 | A-17 | 100 | C-1 | 20 | D-1 | 20 | E-1/E-2 | 4800/2000 |
| Example 18 | R-18 | A-18 | 100 | C-1 | 20 | D-1 | 20 | E-1/E-2 | 4800/2000 |
| Example 19 | R-19 | A-19 | 100 | C-1 | 20 | D-1 | 20 | E-1/E-2 | 4800/2000 |
| Example 20 | R-20 | A-20 | 100 | C-1 | 20 | D-1 | 20 | E-1/E-2 | 4800/2000 |
| Example 21 | R-21 | A-21 | 100 | C-1 | 20 | D-1 | 20 | E-1/E-2 | 4800/2000 |
| Example 22 | R-22 | A-22 | 100 | C-1 | 20 | D-1 | 20 | E-1/E-2 | 4800/2000 |
| Example 23 | R-23 | A-23 | 100 | C-1 | 20 | D-1 | 20 | E-1/E-2 | 4800/2000 |
| Example 24 | R-24 | A-24 | 100 | C-1 | 20 | D-1 | 20 | E-1/E-2 | 4800/2000 |
| Example 25 | R-25 | A-25 | 100 | C-1 | 20 | D-1 | 20 | E-1/E-2 | 4800/2000 |
| Example 26 | R-26 | A-26 | 100 | C-1 | 20 | D-1 | 20 | E-1/E-2 | 4800/2000 |
| Example 27 | R-27 | A-27 | 100 | C-1 | 20 | D-1 | 20 | E-1/E-2 | 4800/2000 |
| Example 28 | R-28 | A-28 | 100 | C-1 | 20 | D-1 | 20 | E-1/E-2 | 4800/2000 |
| Example 29 | R-29 | A-29 | 100 | C-1 | 20 | D-1 | 20 | E-1/E-2 | 4800/2000 |
| Example 30 | R-30 | A-30 | 100 | C-1 | 20 | D-1 | 20 | E-1/E-2 | 4800/2000 |
| Example 31 | R-31 | B-1 | 100 | C-1 | 20 | D-1 | 20 | E-1/E-2 | 4800/2000 |
| Example 32 | R-32 | B-2 | 100 | C-1 | 20 | D-1 | 20 | E-1/E-2 | 4800/2000 |
| Example 33 | R-33 | A-31 | 100 | C-1 | 20 | D-1 | 20 | E-1/E-2 | 4800/2000 |
| Example 34 | R-34 | A-32 | 100 | C-1 | 20 | D-1 | 20 | E-1/E-2 | 4800/2000 |
| Example 35 | R-35 | A-1 | 100 | C-1 | 30 | D-1 | 20 | E-1/E-2 | 4800/2000 |
| Example 36 | R-36 | A-1 | 100 | C-1 | 40 | D-1 | 20 | E-1/E-2 | 4800/2000 |
| Example 37 | R-37 | A-1 | 100 | C-2 | 20 | D-1 | 20 | E-1/E-2 | 4800/2000 |
| Example 38 | R-38 | A-1 | 100 | C-3 | 20 | D-1 | 20 | E-1/E-2 | 4800/2000 |
| Example 39 | R-39 | A-1 | 100 | C-4 | 20 | D-1 | 20 | E-1/E-2 | 4800/2000 |
| Example 40 | R-40 | A-1 | 100 | C-5 | 20 | D-1 | 20 | E-1/E-2 | 4800/2000 |
| Example 41 | R-41 | A-1 | 100 | C-6 | 20 | D-1 | 20 | E-1/E-2 | 4800/2000 |
| Example 42 | R-42 | A-1 | 100 | C-1 | 20 | D-2 | 20 | E-1/E-2 | 4800/2000 |
| Example 43 | R-43 | A-1 | 100 | C-1 | 20 | D-3 | 20 | E-1/E-2 | 4800/2000 |
| Example 44 | R-44 | A-1 | 100 | C-1 | 20 | D-4 | 20 | E-1/E-2 | 4800/2000 |
| Example 45 | R-45 | A-33 | 100 | C-1 | 20 | D-1 | 20 | E-1/E-2 | 4800/2000 |
| Example 46 | R-46 | A-34 | 100 | C-1 | 20 | D-1 | 20 | E-1/E-2 | 4800/2000 |
| Example 47 | R-47 | B-3 | 100 | C-1 | 20 | D-1 | 20 | E-1/E-2 | 4800/2000 |
| Example 48 | R-48 | A-1 | 100 | C-1 | 20 | D-5 | 20 | E-1/E-2 | 4800/2000 |
| Example 49 | R-49 | A-1 | 100 | C-1 | 20 | D-6 | 20 | E-1/E-2 | 4800/2000 |
| Example 50 | R-50 | A-1 | 100 | C-7 | 20 | D-1 | 20 | E-1/E-2 | 4800/2000 |
| Example 51 | R-51 | A-1 | 100 | C-8 | 20 | D-1 | 20 | E-1/E-2 | 4800/2000 |
| Example 52 | R-52 | A-1 | 100 | C-9 | 20 | D-1 | 20 | E-1/E-2 | 4800/2000 |
| Example 53 | R-53 | A-1 | 100 | C-1 | 20 | D-7 | 20 | E-1/E-2 | 4800/2000 |
| Example 54 | R-54 | A-1 | 100 | C-1 | 20 | D-8 | 20 | E-1/E-2 | 4800/2000 |
| Example 55 | R-55 | A-1 | 100 | C-1 | 20 | D-9 | 20 | E-1/E-2 | 4800/2000 |
| Comparative | CR-1 | A-35 | 100 | C-1 | 20 | D-1 | 20 | E-1/E-2 | 4800/2000 |
| Example 1 | | | | | | | | | |
| Comparative | CR-2 | A-36 | 100 | C-1 | 20 | D-1 | 20 | E-1/E-2 | 4800/2000 |
| Example 2 | | | | | | | | | |
| Comparative | CR-3 | A-37 | 100 | C-1 | 20 | D-1 | 20 | E-1/E-2 | 4800/2000 |
| Example 3 | | | | | | | | | |
| Comparative | CR-4 | A-38 | 100 | C-1 | 20 | D-1 | 20 | E-1/E-2 | 4800/2000 |
| Example 4 | | | | | | | | | |
| Comparative | CR-5 | A-39 | 100 | C-1 | 20 | D-1 | 20 | E-1/E-2 | 4800/2000 |
| Example 5 | | | | | | | | | |

<Resist Pattern Formation>

(EUV Exposure, Alkaline Development)

Each of the radiation-sensitive resin compositions prepared above was applied using a spin coater (CLEAN TRACK ACT12 manufactured by Tokyo Electron Ltd.) onto the surface of a 12-inch silicon wafer having a lower layer film with a thickness of 20 nm (AL412 (manufactured by Brewer Science)). After SB was performed at 130° C. for 60 seconds, cooling was performed at 23° C. for 30 seconds to form a resist film having a thickness of 50 nm. Then, the resist film was irradiated with EUV light using an EUV scanner (type “NXE3300”, manufactured by ASML, NA=0.33, lighting condition: Conventional, s=0.89, Mask imecDEFECT32FFR02). Then, the resist film was developed at 23° C. for 30 seconds with a 2.38 wt % aqueous TMAH solution to form a 32 nm positive line-and-space pattern.

### <Evaluation>

The sensitivity, LWR performance, and process window of each of the radiation-sensitive resin compositions were evaluated by measuring each of the resist patterns formed above according to the following method. A scanning electron microscope (“CG-4100” manufactured by Hitachi High-Tech Corporation) was used for measuring the length of the resist pattern. The evaluation results are shown in the following Table 3.

### [Sensitivity]

An exposure amount at which a 32 nm line-and-space pattern was formed in the formation of the resist pattern was defined as an optimum exposure amount, and the optimum exposure amount was defined as sensitivity (mJ/cm²). When the optimum exposure dose was 30 mJ/cm² or less, the sensitivity was determined as “good”, and the optimum exposure dose exceeds 30 mJ/cm², the sensitivity was determined as “poor”.

### [LWR Performance]

The resist pattern was observed from above using the scanning electron microscope. Line widths were measured at a total of 50 optional points. A 3 sigma value was obtained from the distribution of the measurement values, and defined as LWR performance. The smaller the value is, the better the LWR performance is. The LWR performance was determined as “good” in a case of being 4.0 nm or less, and “poor” in a case of exceeding 4.0 nm.

### [Process Window]

A pattern was formed at a low exposure amount to a high exposure amount using a mask forming a 32 nm line-and-space (1L/1S) In general, connection between patterns is observed on a low exposure amount side, and defects such as pattern collapse are observed on a high exposure amount side. The difference between the upper limit value and the lower limit value of the resist dimension in which these defects were not observed was defined as “CD margin”, and the CD margin of 30 nm or more was determined as good, and the CD margin of less than 30 nm was determined as poor. It is considered that the larger the value of the CD margin is, the wider the process window is.

TABLE 3

| | Radiation- | | | |
|---|---|---|---|---|
| | Sensitive | | | CD |
| | Resin | Sensitivity | LWR | Margin |
| | Composition | (mJ/cm²) | (nm) | (nm) |
| Example 1 | R-1 | 26 | 3.6 | 35 |
| Example 2 | R-2 | 27 | 3.6 | 37 |
| Example 3 | R-3 | 28 | 3.6 | 36 |
| Example 4 | R-4 | 27 | 3.7 | 34 |
| Example 5 | R-5 | 29 | 3.7 | 33 |
| Example 6 | R-6 | 28 | 3.9 | 35 |
| Example 7 | R-7 | 29 | 3.4 | 38 |
| Example 8 | R-8 | 29 | 3.5 | 36 |
| Example 9 | R-9 | 28 | 3.6 | 38 |
| Example 10 | R-10 | 30 | 3.8 | 37 |
| Example 11 | R-11 | 30 | 3.7 | 35 |
| Example 12 | R-12 | 28 | 3.6 | 37 |
| Example 13 | R-13 | 29 | 3.4 | 38 |
| Example 14 | R-14 | 27 | 3.8 | 33 |
| Example 15 | R-15 | 25 | 3.9 | 32 |
| Example 16 | R-16 | 26 | 3.4 | 35 |
| Example 17 | R-17 | 25 | 3.5 | 33 |
| Example 18 | R-18 | 25 | 3.8 | 31 |
| Example 19 | R-19 | 29 | 3.7 | 37 |
| Example 20 | R-20 | 27 | 3.4 | 32 |
| Example 21 | R-21 | 28 | 3.6 | 34 |
| Example 22 | R-22 | 25 | 3.5 | 36 |
| Example 23 | R-23 | 29 | 3.6 | 33 |
| Example 24 | R-24 | 28 | 3.5 | 32 |
| Example 25 | R-25 | 29 | 3.4 | 32 |
| Example 26 | R-26 | 28 | 3.4 | 33 |
| Example 27 | R-27 | 29 | 3.7 | 31 |
| Example 28 | R-28 | 29 | 3.6 | 33 |
| Example 29 | R-29 | 27 | 3.8 | 34 |
| Example 30 | R-30 | 28 | 3.2 | 31 |
| Example 31 | R-31 | 29 | 3.9 | 33 |
| Example 32 | R-32 | 29 | 3.7 | 34 |
| Example 33 | R-33 | 28 | 3.7 | 36 |
| Example 34 | R-34 | 30 | 3.8 | 32 |
| Example 35 | R-35 | 25 | 3.8 | 33 |
| Example 36 | R-36 | 23 | 3.9 | 31 |
| Example 37 | R-37 | 29 | 3.5 | 34 |
| Example 38 | R-38 | 27 | 3.7 | 32 |
| Example 39 | R-39 | 29 | 3.4 | 33 |
| Example 40 | R-40 | 28 | 3.6 | 35 |
| Example 41 | R-41 | 29 | 3.5 | 32 |
| Example 42 | R-42 | 27 | 3.5 | 33 |
| Example 43 | R-43 | 25 | 3.8 | 31 |
| Example 44 | R-44 | 28 | 3.4 | 33 |
| Example 45 | R-45 | 30 | 4.0 | 30 |
| Example 46 | R-46 | 28 | 3.8 | 31 |
| Example 47 | R-47 | 29 | 4.0 | 31 |
| Example 48 | R-48 | 30 | 3.8 | 30 |
| Example 49 | R-49 | 28 | 3.9 | 34 |
| Example 50 | R-50 | 26 | 3.8 | 32 |
| Example 51 | R-51 | 25 | 3.7 | 31 |
| Example 52 | R-52 | 25 | 3.9 | 33 |
| Example 53 | R-53 | 28 | 3.8 | 32 |
| Example 54 | R-54 | 27 | 3.8 | 31 |
| Example 55 | R-55 | 29 | 3.9 | 31 |
| Comparative | CR-1 | 28 | 4.2 | 27 |
| Example 1 | | | | |
| Comparative | CR-2 | 26 | 5.3 | 22 |
| Example 2 | | | | |
| Comparative | CR-3 | 27 | 5.1 | 23 |
| Example 3 | | | | |
| Comparative | CR-4 | 31 | 4.8 | 25 |
| Example 4 | | | | |
| Comparative | CR-5 | 28 | 5.2 | 24 |
| Example 5 | | | | |

As apparent from the results shown in Table 3, all the radiation-sensitive resin compositions of Examples were superior in sensitivity, LWR performance, and CD margin to the radiation-sensitive resin compositions of Comparative Examples.

### INDUSTRIAL APPLICABILITY

The radiation-sensitive resin composition and the method for forming a resist pattern according to the present invention make it possible to improve sensitivity, LWR performance, and process margin than ever before. Therefore, they can suitably be used for fine resist pattern formation in the lithography process of various electronic devices such as semiconductor devices and liquid crystal devices.

1: A radiation-sensitive resin composition comprising:
a resin comprising a structural unit A represented by formula (1) and a structural unit B having an acid-dissociable group, wherein the structural unit represented by the formula (1) is excluded from the structural unit B;
a radiation-sensitive acid generator; and
a solvent: 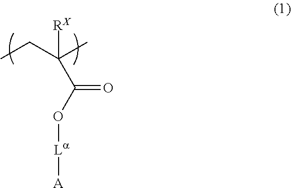
wherein:
R^{X} is a hydrogen atom, a fluorine atom, a methyl group, or a trifluoromethyl group;
A is a monovalent aromatic hydrocarbon group in which —OR^{Y} is bonded to a carbon atom adjacent to a carbon atom to which L^{α} is bonded, and hydrogen atoms on other carbon atoms are unsubstituted, or a part or all of the hydrogen atoms are substituted with a cyano group, a nitro group, an alkyl group, an alkoxy group, an alkoxycarbonyl group, an alkoxycarbonyloxy group, an acyl group, or an acyloxy group;
R^{Y} is a hydrogen atom or a protective group to be deprotected by the action of an acid; and
L^{α} is a single bond, or a divalent linking group.

2: The radiation-sensitive resin composition according to claim 1, wherein in A in the formula (1), —OR^{Y} is not bonded to a carbon atom other than the carbon atom adjacent to the carbon atom to which L^{α} is bonded.

3: The radiation-sensitive resin composition according to claim 1, wherein R^{Y} in the formula (1) is a hydrogen atom.

4: The radiation-sensitive resin composition according to claim 1, wherein the aromatic hydrocarbon group is a phenyl group, a naphthyl group, an anthryl group, a phenanthryl group, or a pyrenyl group.

5: The radiation-sensitive resin composition according to claim 1, wherein the structural unit represented by the formula (1) is a structural unit represented by any one of formulas (1-1) to (1-4): 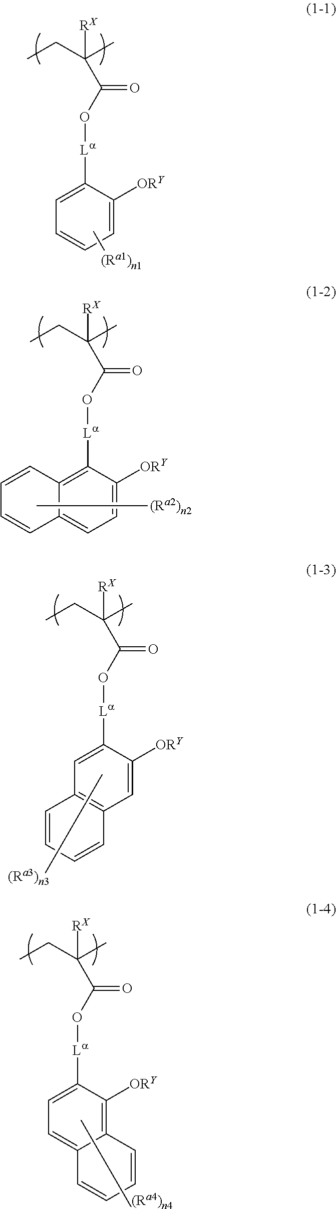
wherein:
R^{X}, R^{Y}, and L^{α} are as defined the same as these in the formula (1),
R^{a1}, R^{a2}, R^{a3}, and R^{a4} are each independently a cyano group, a nitro group, an alkyl group, an alkoxy group, an alkoxycarbonyl group, an alkoxycarbonyloxy group, an acyl group, or an acyloxy group;
n1 is an integer of 0 to 4;
n2, n3, and n4 are each independently an integer of 0 to 6, wherein when there are a plurality of R^{a1}s, R^{a2}s, R^{a3}s, and R^{a4}s, the plurality of R^{a1}s are the same or different from each other, the plurality of R^{a2}s are the same or different from each other, the plurality of R^{a3}s are the same or different from each other, and the plurality of R^{a4}s are the same or different from each other.

6: The radiation-sensitive resin composition according to claim 1, wherein L^{α} is a single bond.

7: The radiation-sensitive resin composition according to claim 1, wherein the resin further comprises a structural unit C represented by formula (cf): 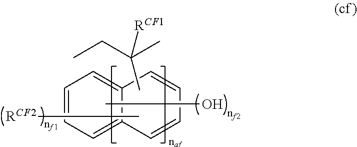
wherein:
R^{CF1} is a hydrogen atom or a methyl group,
R^{CF2} is a monovalent organic group having 1 to 20 carbon atoms or a halogen atom;
n_{f1} is an integer of 0 to 3, wherein when n_{f1} is 2 or 3, the plurality of R^{CF2}s are the same or different from each other, no is an integer of 1 to 3, and n_{f1}+n_{f2} is 5 or less; and
n_{af} is an integer of 0 to 2.

8: The radiation-sensitive resin composition according to claim 1, wherein the acid-dissociable group has a monocyclic or polycyclic alicyclic structure.

9: The radiation-sensitive resin composition according to claim 1, wherein the radiation-sensitive acid generator is represented by formula (p-1): 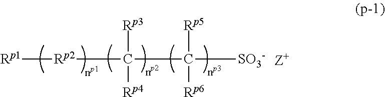
wherein:
R^{p1} is a monovalent group containing a six- or higher-membered ring structure;
R^{p2} is a divalent linking group,
R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms;
R^{p5} and R^{p6} are each independently a fluorine atom or a monovalent fluorinated hydrocarbon group having 1 to 20 carbon atoms,
n^{p1} is an integer of 0 to 10, n^{p2} is an integer of 0 to 10, n^{p3} is an integer of 0 to 10, and n^{p1}+n^{p2}+n^{p3} is an integer of 1 or more and 30 or less, wherein when n^{p1} is 2 or more, a plurality of R^{p2}s are the same or different from each other, when n^{p2} is 2 or more, a plurality of R^{p3}s are the same or different from each other and a plurality of R^{p4}s are the same or different from each other, when n^{p3} is 2 or more, a plurality of R^{p5}s are the same or different from each other and a plurality of R^{p6}s are the same or different from each other; and
Z⁺ is a monovalent onium cation.

10: The radiation-sensitive resin composition according to claim 1, further comprising an onium salt compound that generates an acid having a pKa higher than a pKa of the acid generated from the radiation-sensitive acid generator by irradiation with radiation.

11: The radiation-sensitive resin composition according to claim 1, wherein a content of the structural unit represented by the formula (1) is 5 mol % or more and 70 mol % or less with respect to a total of structural units constituting the resin.

12: A method for forming a resist pattern, comprising:
forming a resist film from the radiation-sensitive resin composition according to claim 1;
exposing the resist film; and
developing the exposed resist film.

13: The method according to claim 12, wherein the exposure is performed using extreme ultraviolet ray or electron beam.

14: The radiation-sensitive resin composition according to claim 5, wherein the structural unit represented by the formula (1) is a structural unit represented by formula (1-1), and n1 is an integer of 1 to 4.
